(19) United States
(12) Patent Application Publication
(10) Pub. No.: US 2026/0075837 A1
(43) Pub. Date: Mar. 12, 2026

(54) SOT MRAM ARRAY INCLUDING SHARED BIT LINE CONNECTION VIA STRUCTURES AND METHOD OF MAKING THE SAME

(71) Applicant: Sandisk Technologies, Inc., Milpitas, CA (US)

(72) Inventors: Jeffrey LILLE, Sunnyvale, CA (US); Nathan FRANKLIN, San Jose, CA (US)

(21) Appl. No.: 18/828,504

(22) Filed: Sep. 9, 2024

(51) Int. Cl. H10B 61/00; G11C 11/16

(52) U.S. Cl. CPC H10B 61/10; G11C 11/1673; G11C 11/1675; H10B 61/22

(57) ABSTRACT

A spin-orbit-torque (SOT) magnetoresistive memory device includes an array of repetition units. Each of the repetition units contains a first magnetic tunnel junction (MTJ) located over and electrically contacting a first lower electrode, a second MTJ located over and electrically contacting a second lower electrode, a spin current metal line located over a top surface of the first MTJ and a top surface of the second MTJ, a first selector element electrically connected to a first end of the spin current metal line, and a second selector element electrically connected to a second end of the spin current metal line.

### FIELD

The present disclosure relates generally to the field of magnetic memory devices, and particularly to a spin-orbit torque magnetoresistive memory array including shared bit line connection via structures and methods of manufacturing the same.

### BACKGROUND

Spin-orbit torque (SOT) magnetoresistive random access memory (MRAM) devices (also known as magnetic random access memory devices) use switching of magnetization direction of a free magnetic layer by injection of an in-plane current in an adjacent conductive layer, which is referred to as a spin-orbit torque (SOT) layer. Unlike spin torque transfer (STT) magnetoresistive random access memory (MRAM) devices in which the write current flows through the magnetic tunnel junction, the write operation is performed by flowing an electrical current through an adjacent conductive layer. The read operation of a SOT memory cell is performed by passing electrical current through the magnetic tunnel junction of the SOT memory cell.

### SUMMARY

According to an aspect of the present disclosure, a spin-orbit-torque (SOT) magnetoresistive memory device includes an array of repetition units. Each of the repetition units contains a first magnetic tunnel junction (MTJ) located over and electrically contacting a first lower electrode, a second MTJ located over and electrically contacting a second lower electrode, a spin current metal line located over a top surface of the first MTJ and a top surface of the second MTJ, a first selector element electrically connected to a first end of the spin current metal line, and a second selector element electrically connected to a second end of the spin current metal line.

### BRIEF DESCRIPTION OF THE DRAWINGS

FIG. 1 is a schematic diagram of a memory device including spin-orbit-torque magnetoresistive random access memory cells in an array configuration according to the embodiments of the present disclosure.

FIG. 2 is a vertical cross-sectional view of an exemplary structure after formation of field effect transistors and lower-level metal interconnect structures embedded in lower-level dielectric material layers according to an embodiment of the present disclosure.

FIG. 3 is a vertical cross-sectional view of the exemplary structure after formation of magnetic tunnel junction stack material layers and mask-level material layers according to an embodiment of the present disclosure.

FIG. 4 is a vertical cross-sectional view of the exemplary structure after patterning the mask-level material layers into mask stacks according to an embodiment of the present disclosure.

FIG. 5 is a vertical cross-sectional view of the exemplary structure after patterning the magnetic tunnel junction stack material layers into magnetic-tunnel-junction-containing pillar structures according to an embodiment of the present disclosure.

FIG. 6 is a vertical cross-sectional view of the exemplary structure after formation of a magnetic-junction-level (MTJ-level) dielectric material layer according to an embodiment of the present disclosure.

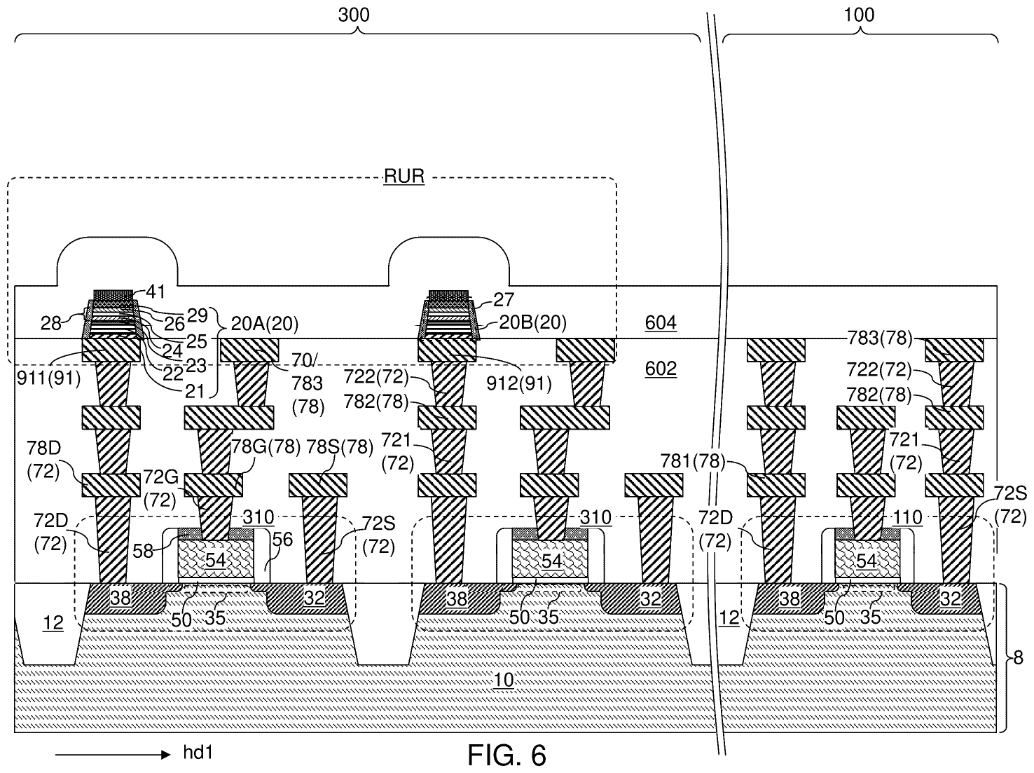

FIG. 7 is a vertical cross-sectional view of the exemplary structure after planarization of the MTJ-level dielectric material layer according to an embodiment of the present disclosure.

FIG. 8 is a vertical cross-sectional view of the exemplary structure after formation of MTJ-level via structures according to an embodiment of the present disclosure.

FIG. 9 is a vertical cross-sectional view of the exemplary structure after formation of spin current metal lines and metal lines according to an embodiment of the present disclosure.

FIG. 10 is a vertical cross-sectional view of the exemplary structure after formation of selector elements according to an embodiment of the present disclosure.

FIG. 11 is a vertical cross-sectional view of the exemplary structure after formation of a first upper-level dielectric material layer and first upper-level metal interconnect structures according to an embodiment of the present disclosure.

FIG. 12 is a vertical cross-sectional view of the exemplary structure after formation of additional upper-level dielectric material layers and additional upper-level metal interconnect structures according to an embodiment of the present disclosure.

FIG. 13A is a plan view of a first configuration of the exemplary structure after the processing steps of FIG. 12.

FIG. 13B is a plan view of a second configuration of the exemplary structure after the processing steps of FIG. 12.

FIG. 14 is a vertical cross-sectional view of a first alternative configuration of the exemplary structure.

FIG. 15 is a vertical cross-sectional view of a second alternative configuration of the exemplary structure.

### DETAILED DESCRIPTION

As discussed above, the present disclosure is directed to a spin-orbit torque magnetoresistive memory array including shared bit line connection via structures and methods of manufacturing the same, the various aspects of which are discussed herein in detail.

The drawings are not drawn to scale. Multiple instances of an element may be duplicated where a single instance of the element is illustrated, unless absence of duplication of elements is expressly described or clearly indicated otherwise. Same reference numerals refer to the same element or to a similar element. Elements having the same reference numerals are presumed to have the same material composition unless expressly stated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, an “in-process” structure or a “transient” structure refers to a structure that is subsequently modified. As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “field effect transistor” refers to any semiconductor device having a semiconductor channel through which electrical current flows with a current density modulated by an external electrical field. As used herein, an “active region” refers to a source region of a field effect transistor or a drain region of a field effect transistor. A “top active region” refers to an active region of a field effect transistor that is located above another active region of the field effect transistor. A “bottom active region” refers to an active region of a field effect transistor that is located below another active region of the field effect transistor.

As used herein, a “conductive material” refers to a material having electrical conductivity greater than 1.0×10⁵ S/cm. As used herein, an “insulating material” or a “dielectric material” refers to a material having electrical conductivity less than 1.0×10⁻⁶ S/cm. As used herein, a “metallic material” refers to a conductive material including at least one metallic element therein. All measurements for electrical conductivities are made at the standard condition.

Magnetization switching via spin-orbit torque (SOT) is a promising alternative to direct spin-transfer torque (STT) for writing bits in magnetoresistive random access memory (MRAM) cells. A typical SOT memory cell includes a nonmagnetic heavy metal SOT layer with strong spin-orbit coupling with, and optionally in contact with, a ferromagnetic free layer that can switch magnetization directions. When an electric write current laterally passes through the nonmagnetic heavy metal SOT layer, spin current is generated in a direction perpendicular to the electrical current via the spin Hall effect (SHE). The spin current exerts a torque on the magnetization of the free layer. Thus, the nonmagnetic heavy metal SOT layer assists in the transition of the magnetization direction in the free layer through the spin Hall effect. Thus, the nonmagnetic heavy metal SOT layer is also referred to as metallic assist layer, i.e., a metallic layer that assists the magnetic transition in the free layer. When a nonmagnetic heavy metal SOT layer is patterned in the shape of a metal line, such a nonmagnetic heavy metal SOT layer is referred to herein as spin current metal line. Since very little electrical current flows through the magnetic tunnel junction (including the free layer) during programming of the memory cell, SOT memory cells generally exhibit higher endurance with lower write error rate than spin-transfer torque (STT) memory cells. In addition, SOT memory cells require lower write-energy than STT memory cells. Finally, SOT switching can achieve nanosecond, and even sub-nanosecond writing speeds.

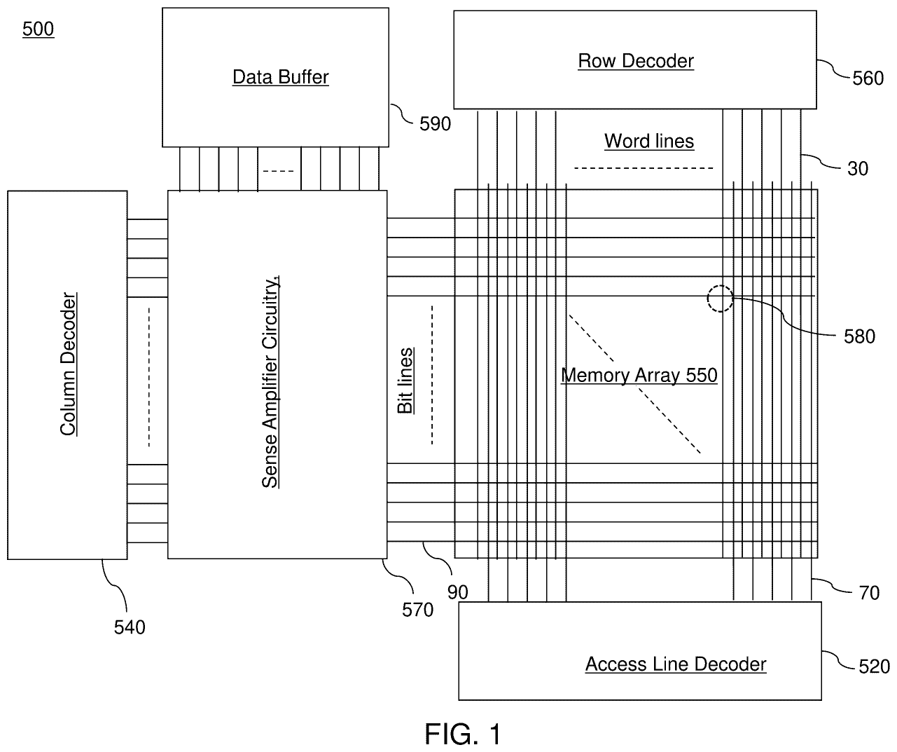

Referring to FIG. 1, a schematic diagram is shown for a memory device 500 including an array of unit cells 580. The memory device 500 may comprise a spin-orbit torque (SOT) magnetoresistive memory device. Each unit cell 580 includes a combination of a magnetoresistive memory cell, an access transistor, and a selector element. The memory device 500 can be configured as a magnetoresistive random access memory (MRAM) device containing spin-orbit torque (SOT) memory cells. As used herein, a “random access memory device” refers to a memory device containing cells that allow random access, e.g., access to any selected memory cell upon a command for reading the contents of the selected memory cell.

The memory device 500 of an embodiment of the present disclosure includes a memory array region 550 containing an array of unit cells 580 located at intersections of word lines (which may comprise first electrically conductive lines 30 as illustrated or as second electrically conductive lines 90 in an alternate configuration) and bit lines (which may comprise second electrically conductive lines 90 as illustrated or as first electrically conductive lines 30 in an alternate configuration). Each unit cell 580 can include a series connection of a SOT memory cell and an access transistor and an optional selector element. Access lines 70 are provided to access the memory cell (e.g., the magnetic tunnel junction) at each cross-point at which a word line intersects a bit line. In one embodiment, the access lines 70 may be connected to a respective row of gate electrodes of the access transistors. In one embodiment, the memory device 500 is in a cross-point array configuration with additional access lines 70 that access a row of access transistors. A source line having a fixed voltage (such as an electrical ground voltage) may be connected to a node of the unit cells 580. For example, the common source line may be electrically connected to the source regions of the access transistors.

The memory device 500 contains a row decoder 560 connected to the word lines, sense circuitry 570 (e.g., a sense amplifier and other bit line control circuitry) connected to the bit lines, a column decoder 540 connected to the bit lines, and a data buffer 590 connected to the sense circuitry. In the embodiment, the memory device 500 can contain an access line decoder 520 connected to access lines 70 if transistor circuit selection elements are used to write to a respective SOT memory cell. Multiple instances of the magnetoresistive memory cells are arranged in an array configuration that forms the memory device 500. It should be noted that the location and interconnection of elements are schematic, and the elements may be arranged in a different configuration. Further, the SOT memory cell of the embodiments of the present disclosure may be manufactured as a discrete device, i.e., a single isolated device.

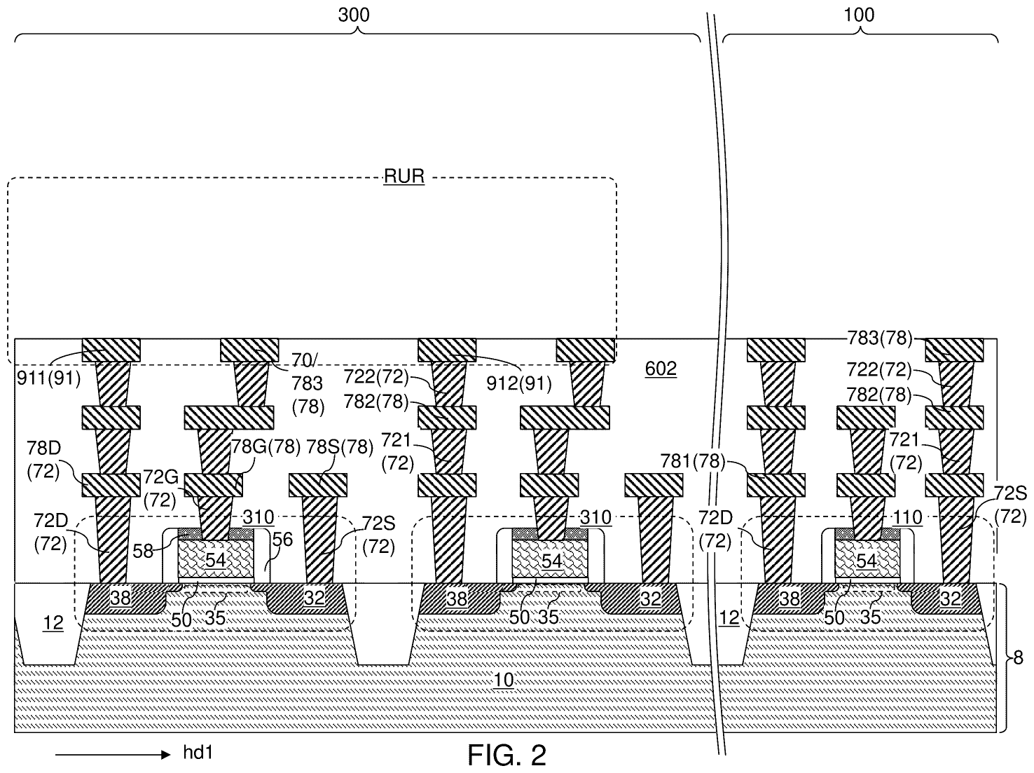

Referring to FIG. 2, an exemplary structure is illustrated. The exemplary structure comprises a substrate 8 including a semiconductor material layer 10, which may be a single crystalline semiconductor material layer such as a single crystalline silicon layer. The semiconductor material layer 10 may comprise a doped well in an upper portion of the substrate 8 or a semiconductor layer that is deposited over the top surface of the substrate 8. In one embodiment, the substrate 8 comprises a semiconductor substrate, such as a commercially available bulk silicon wafer or different semiconductor alloy. In this case, the semiconductor material layer 10 may comprise a doped silicon well in an upper portion of the silicon wafer.

Alternatively, the substrate 8 may comprise a commercially available silicon-on-insulator (SOI) wafer. In this case, the semiconductor material layer 10 may comprise a silicon layer located over an insulating material. Shallow trench isolation structures 12 can be formed in an upper portion of the semiconductor material layer 10. Various semiconductor devices can be formed on and/or in the top portion of the semiconductor material layer 10.

In one embodiment, the exemplary structure comprises a memory array region 300 in which a memory array is formed, and a peripheral region 100 in which peripheral devices configured to control operation of the memory array are formed. The peripheral region 100 may include the above described decoders (520, 540, 560), the sense amplifier circuitry 570 and/or the data buffer 590. The various semiconductor devices that are formed on the semiconductor material layer 10 may comprise field effect transistors (310, 110) and optionally other devices, such as resistors, diodes, capacitors and/or any other suitable semiconductor devices that may be employed as components of the memory array, or may be employed to support operation of the memory array.

In an illustrative example, the shallow trench isolation structures 12 may comprise a two-dimensional array of openings within the memory array region 300, and may have an additional set of openings in the peripheral region 100. Each opening in the shallow trench isolation structures 12 in the memory array region 300 defines an active region for a respective access transistor 310 that controls access to a respective memory cell (e.g., magnetic tunnel junction) to be subsequently formed. Each opening in the shallow trench isolation structures 12 in the peripheral region 100 defines an active region for a respective peripheral transistor 110, which may be employed as a component of the peripheral circuit that is formed in the peripheral region 100. Each of the access transistors 310 and the peripheral transistors 110 may comprise a respective source region 32, a respective drain region 38, a respective channel region 35, a respective gate dielectric 50, a respective gate electrode 54, an optional respective gate cap dielectric 58, and an optional respective dielectric gate spacer 56.

Dielectric material layers and metal interconnect structures (72, 78) can be subsequently formed over the substrate 8 and the field effect transistors (310, 110). A subset of the dielectric material layers that is formed prior to formation of magnetoresistive memory devices is herein referred to as lower-level dielectric material layers 602. A subset of the metal interconnect structures that is formed prior to formation of magnetoresistive memory devices is herein referred to as lower-level metal interconnect structures. The metal interconnect structures (72, 78) comprise metal via structures 72 and metal lines 78. In an illustrative case, the metal via structures 72 embedded within the lower-level dielectric material layers 602 may comprise source contact via structures 72S contacting a source region 32 of a respective field effect transistor (310, 110), drain contact via structures 72D contacting a drain region 38 of a respective field effect transistor (310, 110), gate contact via structures 72G contacting a gate electrode 54 of a respective field effect transistor (310, 110), first-via-level metal via structures 721, and second-via-level metal via structures 722. The metal lines 78 embedded within the lower-level dielectric material layers 602 may comprise source lines 78S that are connected to a respective subset of the source contact via structures 72S, drain connection metal lines 78D that are connected to a respective drain contact via structure 72D, gate connection metal lines 78G that are connected to a respective gate contact via structure 72G, second-line-level metal lines 782 contacting at least one first-via-level metal via structure 721 and/or at least one second-via-level metal via structure 722, and third-line-level metal lines 783 that may contact at least one second-via-level metal via structures 722. In another embodiment, metal component 783 may comprise a metal via as a bottom point contact to a device.

In one embodiment, the channel 35 direction of each access transistor 310 may be parallel to a first horizontal direction hd1. As used herein, a channel direction of a field effect transistor refers to a direction along which a source region 32 and a drain region 38 of the field effect transistor are spaced apart. A second horizontal direction can be defined as a horizontal direction that is perpendicular to the first horizontal direction hd1. In one embodiment, source regions 32 within at least one column of access transistors 310 arranged along the first horizontal direction hd1 may be interconnected to each other by a respective common source line 78S, which laterally extends along the first horizontal direction hd1 with a lateral offset from the drain connection metal lines 78D and the gate connection metal lines 78G within the column of access transistors 310. Alternatively or additionally, source regions 32 within a row of access transistors 310 arranged along the second horizontal direction may be interconnected to each other by the same or different respective common source line 78S, which laterally extends along the second horizontal direction.

In one embodiment, the gate connection metal lines 78G or a subset of the third-line-level metal lines 783 may be employed as the access lines 70. Each access line 70 is electrically connected to a respective row of gate electrodes 54 of access transistors 310 arranged along the second horizontal direction. As such, each access line 70 may be employed to turn on, i.e., activate, a respective row of access transistors 310 arranged along the second horizontal direction. According to an aspect of the present disclosure, another subset of the metal lines 78, such as a subset of the third-line-level metal lines 783, may be employed as first electrodes (e.g., read electrodes) 91 for an array of memory elements (e.g., magnetic tunnel junctions) to be subsequently formed.

The metal interconnect structures (78, 72) comprise at least one metal providing high electrical conductivity. In one embodiment, the metal interconnect structures (78, 72) may comprise a combination of a metallic barrier liner including a conductive metallic barrier material (such as TiN, TaN, WN, MoN, etc.) and a metal fill material such as Al, Cu, W, Mo, Ru, Co, etc.

The peripheral transistors 110 and a subset of the metal interconnect structures (78, 72) formed in the peripheral region 100 can be configured to provide a peripheral circuit. The peripheral circuit is configured to control operation of a memory array in the memory array region 300. The memory array region 300 may include a two-dimensional array of access transistors 310 and a two-dimensional array of SOT memory cells (e.g., magnetic tunnel junctions) and optional selectors to be subsequently formed.

While an embodiment is described in which the lower electrodes 91 of the memory unit cells 580 are formed as a subset of the third-line-level metal lines 783, embodiments are expressly contemplated herein in which the lower electrodes 91 are formed at the level of the first-line-level metal lines 781, at the level of the second-line-level metal lines 782, or at the level of metal lines that are formed at a fourth metal line level or above. Alternatively, the lower electrodes 91 may be formed at a via level, i.e., between neighboring pairs of metal line levels. Generally, each lower electrode 91 may be electrically connected to a drain region 38 of a respective access transistor 310. The top surfaces of the lower electrodes 91 may be formed within a horizontal plane including a topmost surface of the lower-level dielectric material layers 602.

A spin-orbit-torque (SOT) magnetoresistive memory device comprising an array of memory cells and two terminal selector elements can be subsequently formed from the exemplary structure. The array may comprise a two-dimensional periodic array. A pair of memory cells and a pair of respective two terminal selectors can be formed in a repetition unit region RUR. According to an aspect of the present disclosure, a pair of lower electrodes 91 can be formed within each repetition unit region RUR. The pair of lower electrodes 91 comprises a first lower electrode 911 that is electrically connected to a control node of a first access transistor 310 and a second lower electrode 912 that is electrically connected to a control node of a second access transistor 310. The first access electrode 911 and the second access electrode 912 may be embedded within a dielectric material layer such as topmost one of the lower-level dielectric material layers 602.

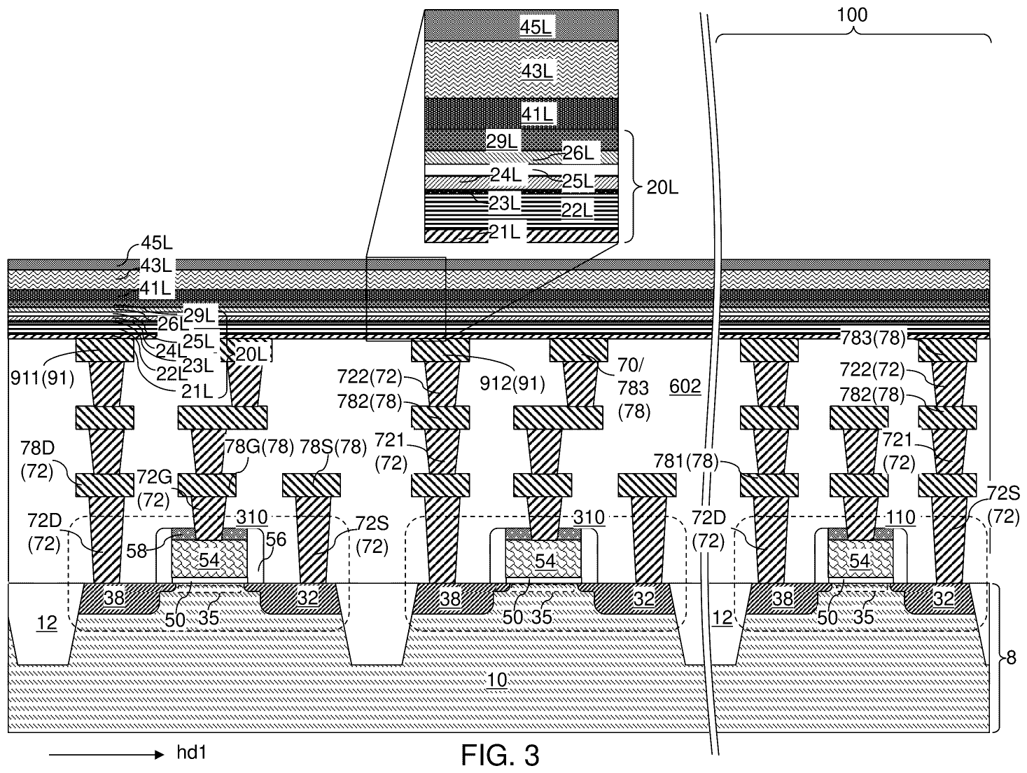

Referring to FIG. 3, magnetic tunnel junction (MTJ) stack material layers 20L and mask-level material layers (41L, 43L, 45L) can be formed over the lower-level dielectric material layers 602 and the lower-level metal interconnect structures (78, 72) that are embedded in the dielectric material layers 602. As used herein, MTJ stack material layers 20L refer to a set of material layers that are subsequently employed to pattern magnetic-tunnel-junction-containing pillar structures, i.e., pillar structures that include a respective magnetic tunnel junction therein. Mask-level material layers (41L, 43L, 45L) refer to material layers that are subsequently employed to form patterned mask structures.

In an illustrative example, the MTJ stack material layers 20L may comprise, from bottom to top, an optional continuous metallic seed layer 21L, a pinning layer 22L, an optional continuous antiferromagnetic coupling layer 23L, a continuous ferromagnetic pinned (i.e., reference) layer 24L, a continuous tunneling barrier layer 25L, a continuous ferromagnetic free layer 26L, and an optional non-ferromagnetic metallic coupling layer 29L. In one embodiment, the pinning layer 22L, the continuous antiferromagnetic coupling layer 23L, and the continuous ferromagnetic pinned layer 24L form a synthetic antiferromagnetic structure (SAF).

The optional continuous metallic seed layer 21L may comprise a metal such as tantalum or platinum. The thickness of the continuous metallic seed layer 21L may be in a range from 1 nm to 10 nm, such as from 2 nm to 4 nm, although lesser and greater thicknesses may also be employed. Alternatively, the continuous metallic seed layer 21L may be omitted.

The pinning layer 22L comprises at least one material layer that can fix the magnetization direction of the continuous pinned (i.e., reference) layer 24L. The pinning layer 22L may comprise a Co/Pt, Co/Pd or Co/Ni superlattice, an exchange-bias-inducing antiferromagnetic layer, such as an IrMn alloy layer, a stack of at least one ferromagnetic material layer and at least one antiferromagnetic layer, or a ferromagnetic material layer that can be coupled to the continuous pinned layer 24L through the continuous antiferromagnetic coupling layer 23L. If the Co/Pt, Co/Pd, or Co/Ni superlattice is used in the pinning layer 22L, then the number of repetitions of a repetition unit (i.e., a bilayer stack) may be in a range from 2 to 20, although lesser and greater numbers of repetition may also be used.

The optional continuous antiferromagnetic coupling layer 23L, if used, comprises a material that can provide antiferromagnetic coupling between the continuous pinned layer 24L and a most proximal ferromagnetic material layer within the pinning layer 22L. The continuous antiferromagnetic coupling layer 23L may comprise a material such as ruthenium, an iridium manganese alloy (if the pinning layer comprises a superlattice), an iron manganese alloy, etc.

The thickness of the continuous antiferromagnetic coupling layer 23L may be in a range from 1 nm to 4 nm, although lesser and greater thicknesses may also be employed. Alternatively, a non-magnetic metal coupling layer may be used instead of the antiferromagnetic coupling layer 23L.

The continuous pinned (i.e., reference) layer 24L comprises a ferromagnetic material. For example, the continuous pinned layer 24L may comprise a ferromagnetic material selected from Ni, Fe, Co, and/or alloys thereof. For example, the continuous pinned layer 24L may comprise CoFe, CoFeB, NiFe, etc. The thickness of the continuous pinned layer 24L may be in a range from 2 nm to 10 nm, such as from 3 nm to 6 nm, although lesser and greater thicknesses may also be employed.

The continuous tunneling barrier layer 25L may comprise insulating material, such as magnesium aluminum oxide spinel or MgO. The thickness of the continuous tunneling barrier layer 25L may be in a range from 0.5 nm to 2 nm, although lesser and greater thicknesses may also be employed.

The continuous free layer 26L may comprise a ferromagnetic material selected from Ni, Fe, Co, and/or alloys thereof, such as CoFe, CoFeB, NiFe, etc. The thickness of the continuous free layer 26L may be in a range from 2 nm to 10 nm, such as from 3 nm to 6 nm, although lesser and greater thicknesses may also be employed. The magnetization direction of the continuous free layer 26L may be parallel to or may be antiparallel to the magnetization direction of the continuous pinned layer 24L.

The optional nonmagnetic metallic coupling layer 29L comprises, and/or consists essentially of, at least one metal. In one embodiment, each metal has a lower resistivity than the spin current metal lines (e.g., the SOT metal layer) to be subsequently formed. In one embodiment, each metal has an atomic number in a range from 72 to 79. In one embodiment, each metal is selected from hafnium, tantalum, tungsten, rhenium, osmium, iridium, platinum, or gold. A metal with a high atomic number is preferable for increasing the spin Hall effect. The nonmagnetic metallic coupling layer 29L may comprise the at least one metal at a total atomic percentage greater than 90 %, and/or greater than 99 %, and/or greater than 99.9 %. The thickness of the nonmagnetic metallic coupling layer 29L can be preferably selected to be as small as possible while ensuring that the top surface of the continuous free layer 26L is not physically exposed during subsequent processing steps. In one embodiment, the thickness of the nonmagnetic metallic coupling layer 29L may be in a range from 1 nm to 20 nm, such as from 2 nm to 6 nm, although lesser and greater thicknesses may also be employed. Alternatively, the nonmagnetic metallic coupling layer 29L may be omitted.

The nonmagnetic metallic coupling layer 29L is deposited in the same process as the deposition of the previous free layer 26L to avoid interface issues. In alternative embodiments, the coupling layer 29L may comprise a synthetic antiferromagnet, a ferrimagnet whose magnetic moment is less than 10% of free layer 26L, or a Heusler compound which includes a metal having an atomic number in a range from 25 to 28. In one embodiment, an additional interface layer may be present between the free layer 26L and the coupling layer 29L to prevent interdiffusion between the free layer 26L and the coupling layer 29L.

The mask-level material layers (41L, 43L, 45L) comprise a suitable material layer stack that may be patterned and subsequently employed as an etch mask during patterning of the MTJ stack material layers 20L. If an ion beam etching (IBE) process is subsequently employed to pattern the MTJ stack material layers 20L, the mask-level material layers (41L, 43L, 45L) comprise a suitable set of material layers that can be employed as an etch mask during the IBE process. In an illustrative example, the mask-level material layers (41L, 43L, 45L) may comprise, from bottom to top, a first metal mask layer 41L, a carbon-based mask layer 43L, and a second metal mask layer 45L. In an illustrative example, the first metal mask layer 41L may comprise tantalum nitride, the carbon-based mask layer 43L may comprise diamond-like carbon (DLC), and the second mask layer 45L may comprise an etchable hardmask such as chromium or a sacrificial material.

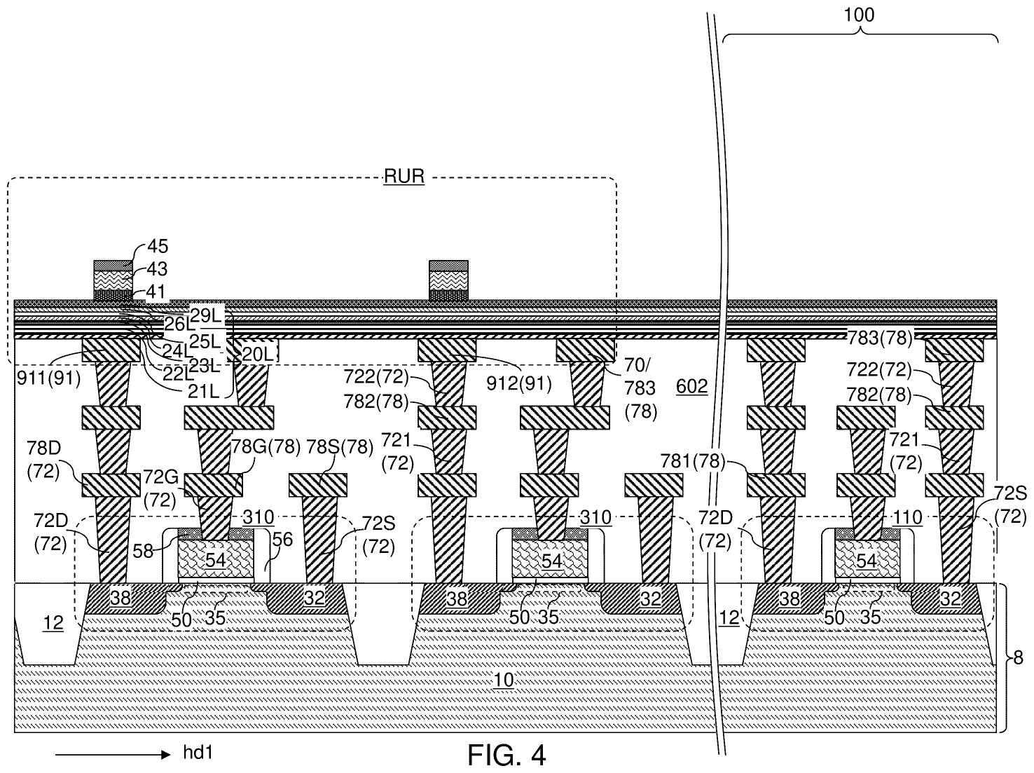

Referring to FIG. 4, a photoresist layer (not shown) can be applied over the mask-level material layers (41L, 43L, 45L), and can be lithographically patterned to form a two-dimensional array of discrete photoresist material portions. Each discrete photoresist material portion may overlie a respective one of the lower electrodes 91, and may be located entirely within the area of the respective one of the lower electrodes 91 in a plan view (such as a top-down view). In one embodiment, the lower electrodes 91 may be arranged as a periodic two-dimensional array having a first periodicity along the first horizontal direction hd1 and having a second periodicity along the second horizontal direction, and the discrete photoresist material portions may be arranged as a periodic two-dimensional array having the same two-dimensional periodicity as the periodic two-dimensional array of the lower electrodes 91. The horizontal cross-sectional shape of each discrete photoresist material portion may be a circle, an ellipse, a rounded rectangle, a rectangle, or any other closed curvilinear shape having a closed periphery.

An IBE and/or a reactive ion etch process can be performed to transfer the pattern of the array of discrete photoresist material portions through the mask-level material layers (41L, 43L, 45L). The patterned portions of the mask-level material layers (41L, 43L, 45L) comprise a two-dimensional array of mask patterns (41, 43, 45). Each mask pattern (41, 43, 45) may comprise a respective stack of a first metal mask portion 41, a carbon-based mask portion 43, and a second metal mask portion 45. The photoresist layer can be subsequently removed, for example, by ashing.

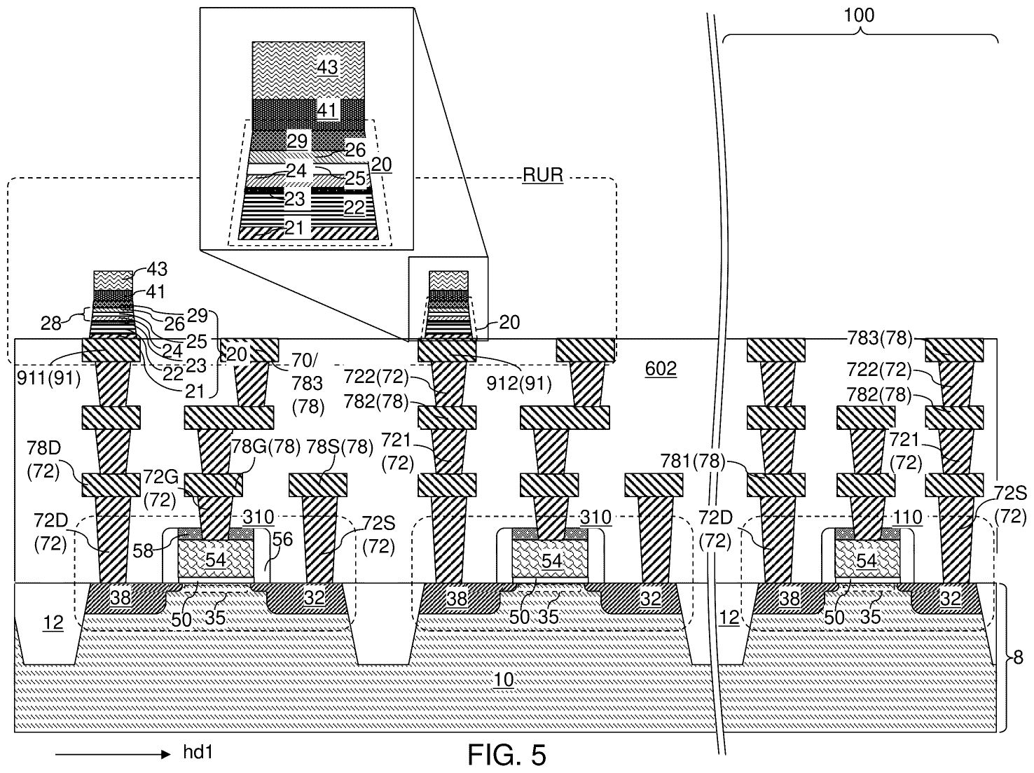

Referring to FIG. 5, an ion beam etch process can be performed to transfer the pattern of a two-dimensional array of mask patterns (41, 43, 45) through the MTJ stack material layers 20L. The MTJ stack material layers 20L are patterned into a two-dimensional array of magnetic-tunnel-junction-containing pillar structures 20, which are also referred to as MTJ-containing pillar structures 20. As used herein, a magnetic-tunnel-junction-containing pillar structures refer to pillar structures that contain a magnetic tunnel junction therein.

Each MTJ-containing pillar structure 20 can be formed on a top surface of a respective lower electrode 91. Each MTJ-containing pillar structure 20 may comprise, from bottom to top, an optional metallic seed layer 21, a pinning structure 22, an optional antiferromagnetic coupling layer 23, a pinned layer 24, a tunneling barrier layer 25, a free layer 26, and a nonmagnetic coupling layer 29. The metallic seed layer 21 is a patterned portion of the continuous metallic seed layer 21L, the pinning structure 22 is a patterned portion of the pinning layer 22L, the antiferromagnetic coupling layer 23 is a patterned portion of the continuous antiferromagnetic coupling layer 23L, the pinned layer 24 comprises a patterned portion of the continuous pinned layer 24L, the tunneling barrier layer 25 comprises a patterned portion of the continuous tunneling barrier layer 25L, the free layer 26 comprises a patterned portion of the continuous free layer 26L, and the nonmagnetic coupling layer 29 comprises a portion of the nonmagnetic metallic coupling layer 29L. The combination of the pinned layer 24, the tunneling barrier layer 25, the free layer 26 constitutes a magnetic tunnel junction structure 28.

Each MTJ-containing pillar structure 20 may have a respective tapered sidewall. The taper angle of the tapered sidewalls of the MTJ-containing pillar structures 20, as measured relative to the vertical direction, may be in a range from 0.1 degree to 20 degrees, such as from 1 degree to 10 degrees, although lesser and greater taper angles may also be employed.

Each MTJ-containing pillar structure 20 contacts a top surface of a respective lower electrode 91, and comprises a pinned layer 24 and a free layer 26 that overlies the pinned layer 24. In one embodiment, each MTJ-containing pillar structure 20 comprises a pinning structure 22 that underlies and is magnetically coupled to the pinned layer 24. The pinning structure 22 pins the magnetization direction of the pinned layer 24. The pinning structure 22, the antiferromagnetic coupling layer 23 and the pinned layer 24 may comprise a synthetic antiferromagnetic (SAF) or an exchange-biased layer structure. In one embodiment, each MTJ-containing pillar structure 20 may comprise a nonmagnetic coupling layer 29 in direct contact with a top surface of the free layer 26 and comprising at least one metal having an atomic number in a range from 72 to 79 at a total atomic percentage greater than 99 %. In one embodiment, a periphery of a bottom surface of the nonmagnetic coupling layer 29 coincides with a periphery of a top surface of the free layer 26 within each MTJ-containing pillar structure 20. In other words, a bottom periphery of the nonmagnetic coupling layer 29 may coincide with a top periphery of the free layer 26. Alternatively, the nonmagnetic coupling layer 29 may be omitted.

The second metal mask portions 45 may be removed during patterning of the MTJ stack material layers 20L into the MTJ-containing pillar structures 20. The carbon-based mask portions 43 may partially remain after patterning the MTJ stack material layers 20L into the MTJ-containing pillar structure 20. The first metal mask portions 41 may be present after patterning the MTJ stack material layers 20L into the MTJ-containing pillar structure 20.

According to an aspect of the present disclosure, two MTJ-containing pillar structures 20 can be formed within each repetition unit region RUR. The two MTJ-containing pillar structures 20 that are formed within each repetition unit region RUR may comprise a first magnetic-tunnel-junction-containing (MTJ-containing) pillar structure (e.g., an MTJ of a first SOT MRAM cell) 20A that is formed on a top surface of a first lower electrode 911 and a second MTJ-containing pillar structure (e.g., an MTJ of a second SOT MRAM cell) 20B that is formed on a top surface of a second lower electrode 912.

In one embodiment, within each of the unit cells regions RUR, the first MTJ-containing pillar structure 20A may comprise a first free layer 26, and the second MTJ-containing pillar structure 20B may comprise a second free layer 26. In one embodiment, within each of the unit cells regions RUR, the first MTJ-containing pillar structure 20A may comprise a first tunneling barrier layer 25 and a first pinned layer 24 that underlie the first free layer 26, and the second MTJ-containing pillar structure 20B may comprise a second tunneling barrier layer 25 and a second pinned layer 24 that underlie the second free layer 26.

Referring to FIG. 5, the carbon-based mask portions 43 may be removed selectively to the first metal mask portions 41, for example, by performing an ashing process. A dielectric material layer can be deposited around the two-dimensional array of MTJ-containing pillar structures 20 and the first metal mask portions 41. The dielectric material layer is herein referred to as a magnetic-junction-level dielectric material layer 604, or an MTJ-level dielectric material layer 604. The dielectric material of the MTJ-level dielectric material layer 604 may comprise silicon nitride, undoped silicate glass (i.e., silicon oxide), a doped silicate glass, organosilicate glass, etc. The dielectric material of the MTJ-level dielectric material layer 604 may be deposited by chemical vapor deposition, atomic layer deposition or spin-coating. The thickness of a horizontally-extending portion of the MTJ-level dielectric material layer 604 is greater than the height of each MTJ-containing pillar structure 20.

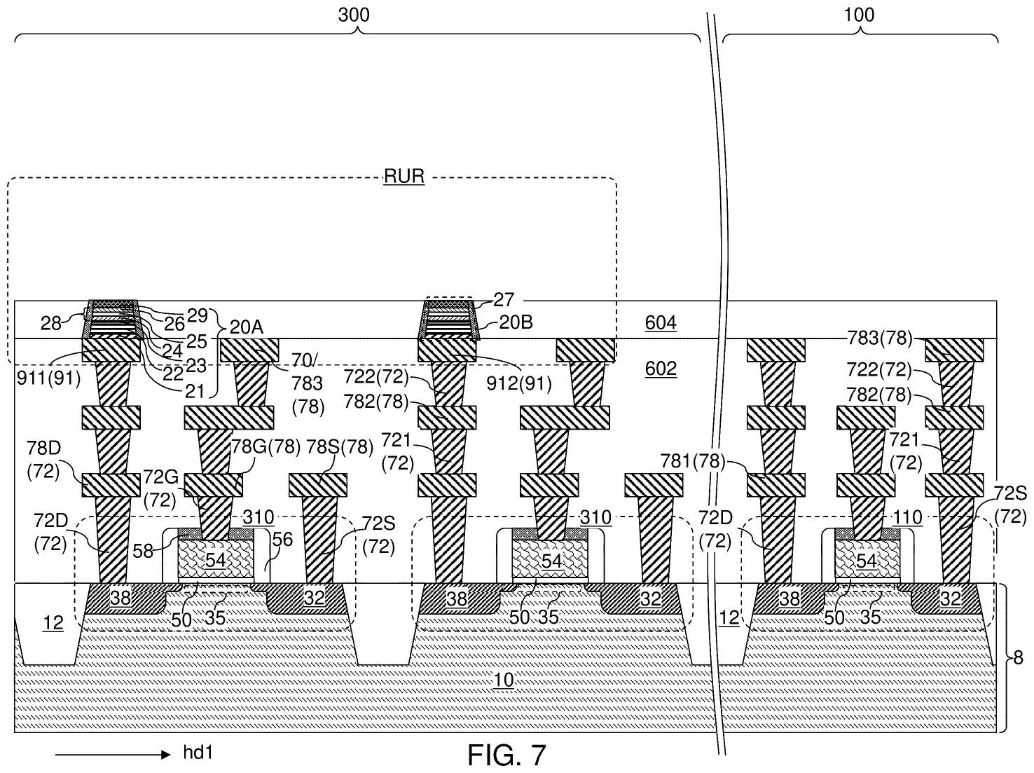

Referring to FIG. 7, a planarization process can be performed to remove the first metal mask portions 41 and portions of the MTJ-level dielectric material layer 604 that overlie a horizontal plane including the top surfaces of the MTJ-containing pillar structure 20, i.e., the horizontal plane including the top surfaces of the nonmagnetic coupling layers 29. The planarization process may comprise a chemical mechanical polishing (CMP) process. In one embodiment, the first metal mask portions 41 may be employed as stopping structures during removal of portions of the MTJ-level dielectric material layer 604 that overlie the horizontal plane including the top surfaces of the first metal mask portions 41. Subsequently, the MTJ-level dielectric material layer 604 may be vertically recessed, and the first metal mask portions 41 may be removed selectively to the material of the nonmagnetic coupling layers 29.

In an alternative embodiment, the separate removal of the mask patterns (41, 43, 45) described above may be omitted. Instead, the mask patterns (41, 43, 45) may be removed during the CMP process which planarizes the MTJ-level dielectric material layer 604. In this alternative embodiment, the top surfaces of the nonmagnetic coupling layers 29 are used as polish stop structures. In various embodiments, the top surface of the MTJ-level dielectric material layer 604 after the planarization process may be coplanar with the top surfaces of the nonmagnetic coupling layers 29.

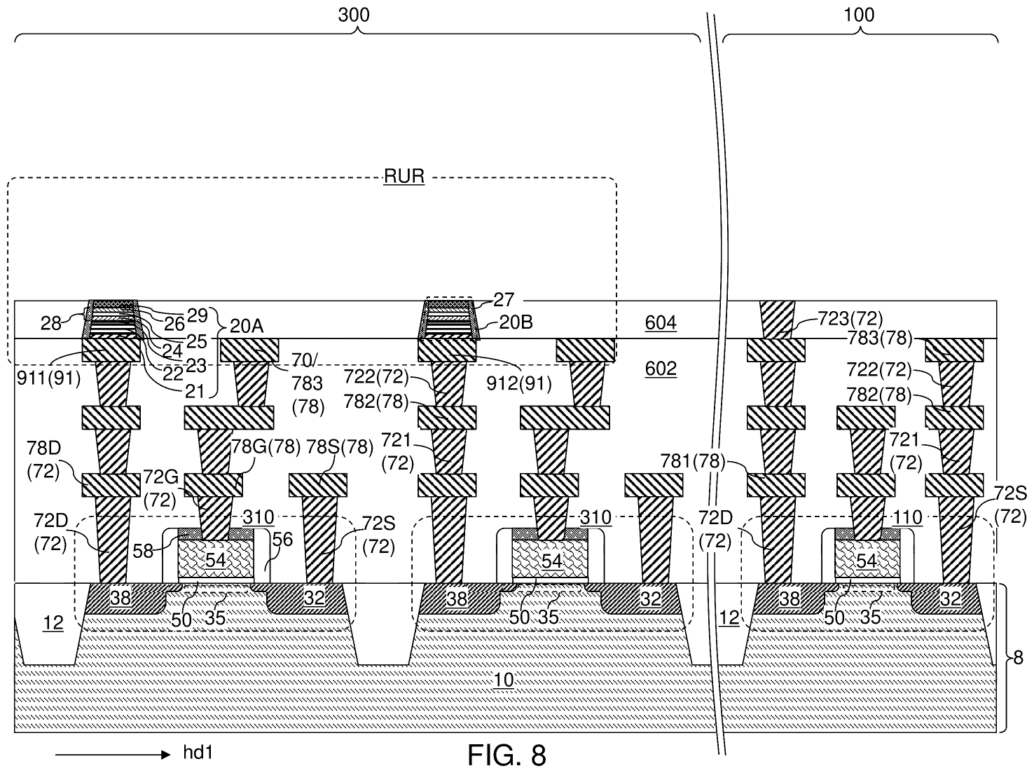

Referring to FIG. 8, via cavities can be formed through the MTJ-level dielectric material layer 604 in the peripheral region 100 over areas of a subset of the third-line-level metal lines 783. At least one metallic material can be deposited in the via cavities, and excess portions of the at least one metallic material can be removed from above the horizontal plane including the top surface of the MTJ-level dielectric material layer 604 by a planarization process. Remaining portions of the at least one metallic material filling the via cavities constitute metal via structures, which are herein referred to as third-via-level metal via structures 723, which are also referred to as MTJ-level via structures.

It should also be noted that the order of operations may be altered. As an example, a metal layer may be deposited over the lower-level dielectric material layers 602 and patterned (e.g., etched) to form the metal via 723 prior to the formation of the MTJ-level dielectric material layer 604.

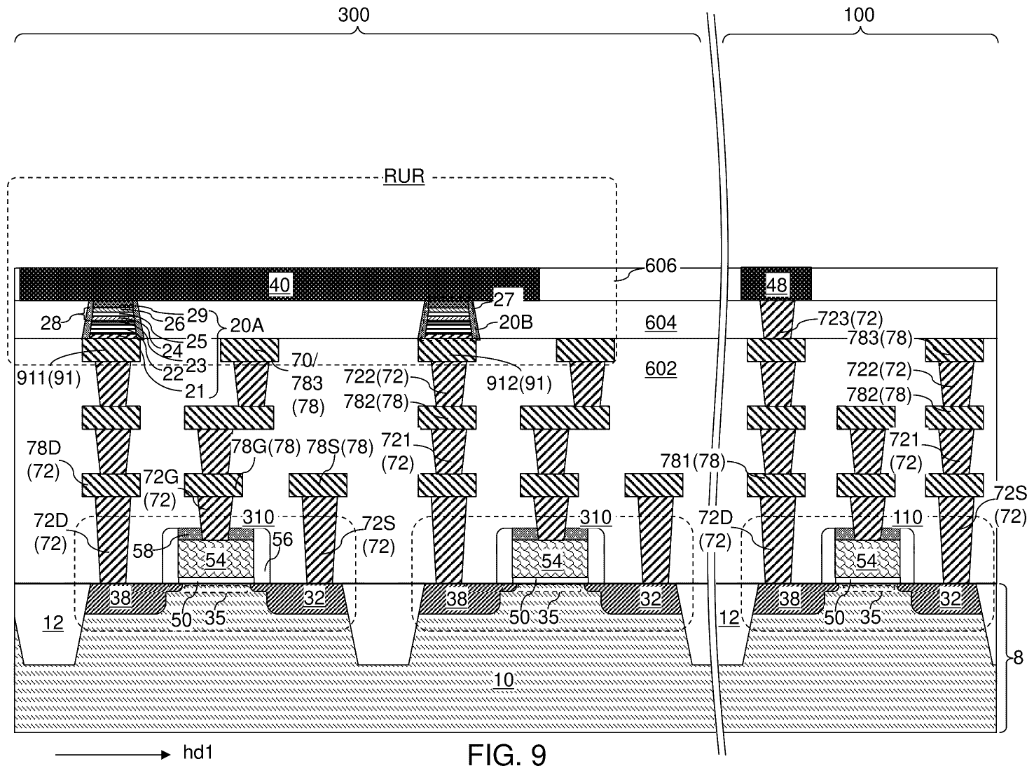

Referring to FIG. 9, a SOT metal layer is deposited over the two-dimensional array of MTJ-containing pillar structures 20. The SOT metal layer may comprise at least one second metal or metal alloy having large spin-orbit coupling strength, such as Pt, Ta, W, Hf, Ir, CuBi, CuIr, AuPt, AuW, PtPd, etc. In one embodiment, the SOT metal layer may comprise an elemental metal having an atomic number in a range from 72 to 79 (e.g., Pt, Ta, W, Hf or Ir) at a total atomic percentage greater than 90 %, and/or greater than 99 %, and/or greater than 99.9 %. Alternatively the SOT metal layer may comprise an alloy of two or more metals having an atomic number between 72 and 79, or an alloy of at least one metal having an atomic number between 72 and 79 and an additional metal not having an atomic number between 72 and 79 in which the additional metal has an atomic percentage less than 50%. The SOT metal layer may be deposited by physical vapor deposition or chemical vapor deposition. The thickness of the SOT metal layer may be in a range from 5 nm to 25 nm, although lesser and greater thicknesses may also be employed.

A photoresist layer (not shown) can be applied over the heavy metal SOT layer, and can be lithographically patterned into discrete photoresist material portions. The discrete photoresist material portions may comprise a two-dimensional periodic array line-shaped photoresist material portions that are formed in the memory array region 300, and additional discrete photoresist material portions that are formed in the peripheral region 100. An anisotropic etch process can be performed to remove portions of the heavy metal SOT layer that are not masked by the patterned portions of the photoresist layer.

Remaining portions of the heavy metal SOT layer that remains in the memory array region 300 comprise a two-dimensional array of spin current metal lines (e.g., SOT lines) 40. The spin current metal lines 40 are metal lines that may comprise and/or consist essentially of the at least one second metal or metal alloy and elongated along the first horizontal direction hd1. Generally, the spin current metal lines 40 are used to flow a write current that imparts a spin to underlying free layers 26 through the spin Hall effect.

In one embodiment, each pair of a first MTJ-containing pillar structure 20A and a second MTJ-containing pillar structure 20B within a repetition unit region RUR may be laterally spaced apart along a first horizontal direction hd1, and the spin current metal lines 40 may laterally extend along the first horizontal direction hd1 with a uniform vertical cross-sectional area within vertical planes that are perpendicular to the first horizontal direction hd1. Each spin current metal line 40 may be formed within a respective repetition unit region RUR, and may comprise a first portion that contacts a top surface of a first MTJ-containing pillar structure 20A within the repetition unit region RUR and a second portion that contacts a top surface of a second MTJ-containing pillar structure 20B within the repetition unit region RUR. A center portion of the spin current metal line 40 can be located between the first MTJ-containing pillar structure 20A and the second MTJ-containing pillar structure 20B. Further, a first end portion of the spin current metal line 40 can laterally extend farther along the first horizontal direction hd1 than a distal sidewall segment of the first MTJ-containing pillar structure 20A, and a second end portion of the spin current metal line 40 can laterally extend farther along the first horizontal direction hd1 than a distal sidewall segment of the second MTJ-containing pillar structure 20B.

The width of each spin current metal line 40 along the second horizontal direction may be a minimum lithographic width (which is typically represented by the letter “F”). The minimum lithographic width refers to the minimum lateral dimension that can be printed employing a lithographic exposure and development process. The length of each spin current metal line 40 along the first horizontal direction hd1 may be in a range from three times the minimum lithographic width to five times the minimum lithographic width, although lesser and greater lengths along the first horizontal direction hd1 may also be employed.

In one embodiment, the nonmagnetic coupling layers 29 (if present) have a lower electrical resistivity than the spin current metal lines 40 and are thinner than the spin current metal lines 40 to maximize the spin Hall effect on the free layers 26. In one embodiment, the ratio of the thickness of the nonmagnetic coupling layers 29 to the height (i.e., the vertical thickness) of the spin current metal lines 40 may be in a range from 0.005 to 0.2, such as from 0.01 to 0.1, although lesser and greater ratios may also be employed. Alternatively, the nonmagnetic coupling layer 29 may be omitted, and the free layers 26 of the first MTJ-containing pillar structure 20A and the second MTJ-containing pillar structure 20B may directly contact a respective bottom surface segment of the spin current metal line 40.

In one embodiment, remaining patterned portions of the SOT metal layer in the peripheral region 100 may comprise metal lines 48. The metal lines 48 have the same material composition and the same thickness as the spin current metal lines 40. The metal lines 48 may contact a top surface of a respective underlying metal via structure such as a third-via-level metal via structure 723. In one embodiment, the peripheral circuit may comprise a subset of the metal lines 48 as components of the metal interconnect structures.

A spin-current-level dielectric material layer 606 can be deposited in the gaps between the two-dimensional array of spin current metal lines 40 and the metal lines 48. The spin-current-level dielectric material layer 606 comprises a dielectric material such as silicon nitride, undoped silicate glass, a doped silicate glass, or organosilicate glass. Excess portions of the dielectric material can be removed from above the horizontal plane including the top surfaces of the spin current metal lines 40 by a planarization process, such as a chemical mechanical polishing process. In this case, the top surface of the spin-current-level dielectric material layer 606 can be formed within the horizontal plane including the top surfaces of the spin current metal lines 40.

In an alternative embodiment, a damascene process may be used in which the spin-current-level dielectric material layer 606 is formed prior to formation of the two-dimensional array of spin current metal lines 40 and the heavy metal lines 48. Line cavities can be formed in the spin-current-level dielectric material layer 606, and can be filled with the at least one second metal by physical vapor deposition or chemical vapor deposition. Excess portions of the at least one second metal can be removed from above the horizontal plane including the top surface of the spin-current-level dielectric material layer 606 by performing a planarization process, such as a chemical mechanical polishing process. Remaining portions of the at least one second metal comprise the two-dimensional array of spin current metal lines 40 and the metal lines 48.

In summary, a common spin current metal line 40 contacting a top surface of the first MTJ-containing pillar structure 20A and a top surface of the second MTJ-containing pillar structure 20B is formed within each repetition unit region RUR. Thus, two SOT MRAM cell MTJs 20A and 20B share a common spin current metal line (i.e., a common SOT metal layer) 40. In one embodiment, the spin current metal line 40 may laterally extend along a first horizontal direction hd1 with a uniform vertical cross-sectional area along vertical planes that are perpendicular to the first horizontal direction hd1. In one embodiment, the first MTJ-containing pillar structure 20A and the second MTJ-containing pillar structure 20B are laterally spaced apart from each other along the first horizontal direction hd1. In one embodiment, the spin current metal line 40 comprises at least one metal having a respective atomic number in a range from 72 to 79 at a total atomic percentage greater than 99 %. In one embodiment, within each of the unit cell regions RUR, the first MTJ-containing pillar structure 20A comprises a first free layer 26 underlying a first bottom surface segment of the spin current metal line 40, and the second MTJ-containing pillar structure 20B comprises a second free layer 26 underlying a second bottom surface segment of the spin current metal line 40.

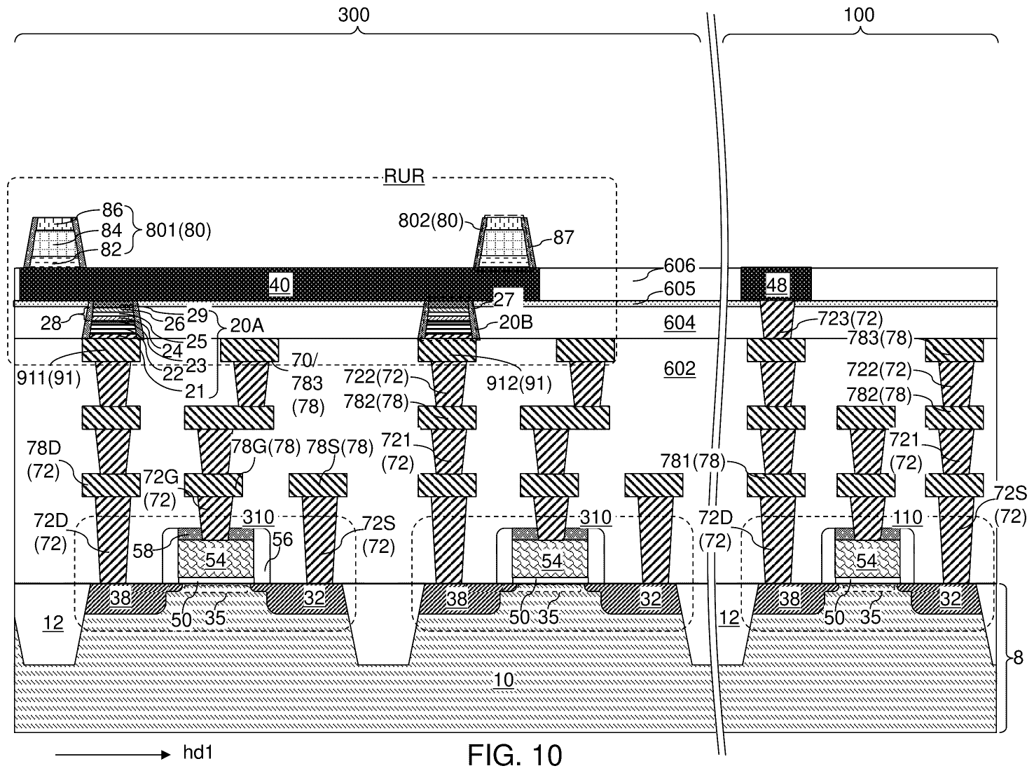

Referring to FIG. 10, a two-dimensional array of selector elements 80 can be formed over the two-dimensional array of spin current metal lines 40. For example, a lower selector electrode material layer, a non-Ohmic material layer, and an upper selector electrode material layer can be sequentially deposited over the two-dimensional array of spin current metal lines 40 and the spin-current-level dielectric material layer 606. A photoresist layer (not shown) can be applied over the upper selector electrode material layer, and can be lithographically patterned into a periodic two-dimensional array of photoresist material portions that overlie the two-dimensional array of spin current metal lines 40. Each patterned portion of the photoresist layer can be formed entirely within the area of a respective one of the spin current metal lines 40 in a plan view, such as a top-down view. Specifically, each patterned portion of the photoresist layer may be formed entirely within the area of a first end portion of the respective one of the spin current metal lines 40.

An anisotropic etch process can be performed to remove portions of the upper selector electrode material layer, the non-Ohmic material layer, and the upper selector electrode material layer that are not masked by the patterned portions of the photoresist layer. Each patterned portion of the upper selector electrode material layer comprises an upper selector electrode 86. Each patterned portion of the non-Ohmic material layer comprises a non-Ohmic material portion 84. Each patterned portion of the lower selector electrode material layer comprises a lower selector electrode 82.

The lower selector electrodes 82 and the upper selector electrodes 86 may comprise a respective non-metallic conductive material. Exemplary non-metallic conductive materials that can be employed for the lower selector electrodes 82 and the upper selector electrodes 86 include amorphous carbon, amorphous boron-doped carbon, amorphous metal-doped carbon, amorphous nitrogen-doped carbon, and layer stacks thereof. The non-Ohmic material portions 84 provide non-Ohmic resistive characteristics as a function of an applied electrical voltage thereacross. For example, the non-Ohmic material portion 84 may comprise an ovonic threshold switch material, a conductive bridge material, a diode, or any other non-Ohmic switching material or structure that can switch between different resistivity states above a threshold voltage. For example, the ovonic threshold switch material can be a chalcogenide compound, such as a telluride compound, a selenide compound, a sulfide compound, a selenide-sulfide compound, a silicon-telluride compound, a silicon-selenide compound, a selenide-telluride compound, or a sulfide-selenide-telluride compound. Exemplary ovonic threshold switch materials include, but are not limited to zinc telluride compounds (such as Zn₁₋ₓTeₓ), germanium telluride compounds, germanium selenide compounds doped with a dopant selected from As, N, and C, such as a Ge—Se—As. In one embodiment, the ovonic threshold switch material layer can include, and/or can consist essentially of, GeS alloy, a SiS alloy, a GeSeAs alloy, a ZnTe alloy, a GeSe alloy, a SeAs alloy, a GeTe alloy, a SiTe alloy, or comprise of combinations thereof. Each contiguous stack of a lower selector electrode 82, a non-Ohmic material portion 84, and an upper selector electrode 86 constitutes a selector element 80.

Each selector element 80 can be formed directly on, and can be electrically connected to, a top surface segment of an end of a respective spin current metal line 40. Thus, each selector element 80 can contact a segment of the top surface of the respective spin current metal line 40. In one embodiment, the selector element 80 comprises a two-terminal selector element including a non-Ohmic material portion 84 that provides non-Ohmic resistive characteristics as a function of an applied electrical voltage thereacross. In one embodiment, each non-Ohmic material portion 84 comprises an ovonic threshold switch material.

In summary, a pair of selector elements 80 is formed within each repetition unit region RUR. The pair of selector elements 80 comprises a first selector element 801 that is formed on a first end of the spin current metal line 40, and a second selector element 802 that is formed on a second end of the spin current metal line 40. The first selector element 801 and the second selector element 802 are laterally spaced apart from each other along the first horizontal direction hd1. In one embodiment, the lateral spacing between the first selector element 801 and the second selector element 802 is greater than a lateral spacing between the first MTJ-containing pillar structure 20A and the second MTJ-containing pillar structure 20B.

The first selector element 801 is electrically connected to a first end of the spin current metal line 40, and the second selector element 802 is electrically connected to a second end of the spin current metal line 40. The top surface of the first MTJ-containing pillar structure 20A is located between the first selector element 801 and the bit line connection via structure 93 in a plan view such as a top-down view. The top surface of the second MTJ-containing pillar structure 20B is located between the second selector element 802 and the bit line connection via structure 93 in the plan view. Thus, the first selector element 801 functions as a selector element for the first MTJ-containing pillar structure (i.e., the MTJ of the first SOT MRAM cell) 20A, while the second selector element 802 functions as a selector element for the second MTJ-containing pillar structure (i.e., the MTJ of the second SOT MRAM cell) 20B. In one embodiment, each of the first selector element 801 and the second selector element 802 comprises a respective non-Ohmic material portion that provides non-Ohmic resistive characteristics as a function of an applied electrical voltage thereacross. In one embodiment, the non-Ohmic material portion comprises an ovonic threshold switch material.

In one embodiment, each selector element 80 may have a respective tapered sidewall. The taper angle of the tapered sidewalls of the selector elements 80, as measured relative to the vertical direction, may be in a range from −5 degree to 20 degrees, such as a preferred 0 degrees, although lesser and greater taper angles may also be employed. The selector element 80 may be offset along the first horizontal direction hd1 from the respective underlying MTJ-containing pillar structure 20 that contacts the same spin current metal line 40 as the selector element 80. The selector element 80 contacts the top surface of the respective spin current metal line 40 and the MTJ-containing pillar structure 20 contacts the bottom surface of the same spin current metal line 40. Thus, the selector element 80 and the respective MTJ-containing pillar structure 20 are located on opposite vertical sides of the respective spin current metal line 40 and are laterally offset from each other along the first horizontal direction hd1.

Optionally, dielectric selector spacers 87 may be formed around the selector elements 80, for example, by depositing and anisotropically etching a conformal passivation dielectric material layer. The dielectric selector spacers 87 may comprise a passivation dielectric material such as silicon nitride or silicon carbonitride. The lateral thickness of the dielectric selector spacers 87 may be in a range from 3 nm to 30 nm, although lesser and greater thicknesses may also be employed.

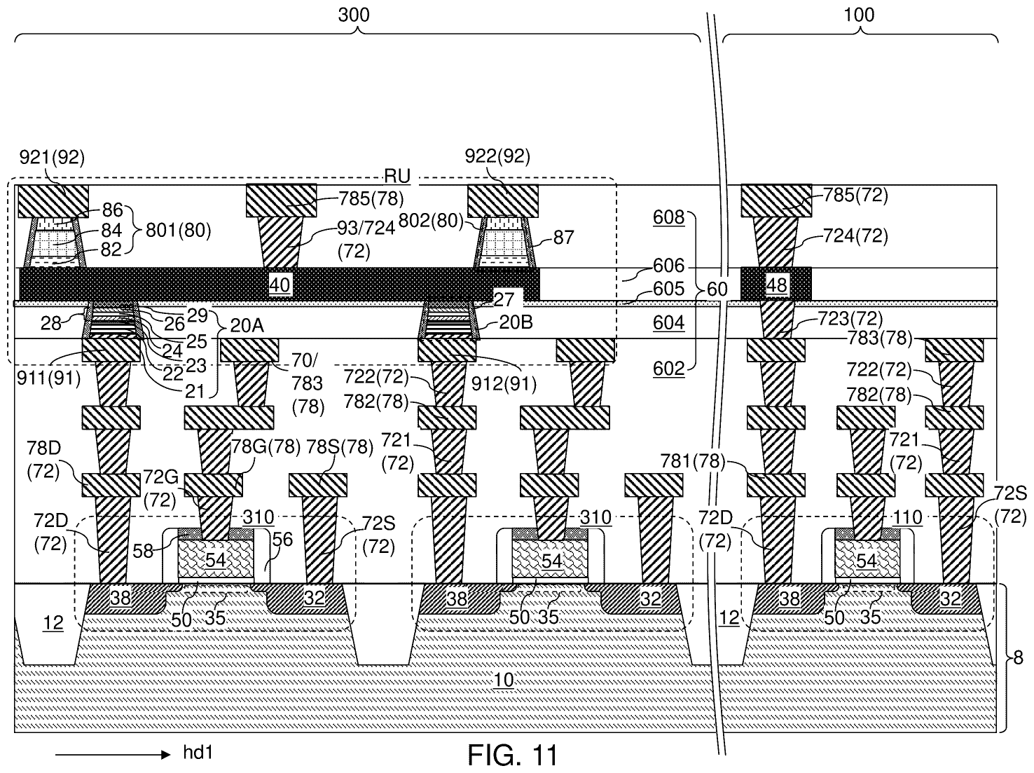

Referring to FIG. 11, a first upper-level dielectric material layer 608 can be deposited over the two-dimensional array of selector elements 80. Via cavities and line cavities may be formed in the first upper-level dielectric material layer 608, and can be filled with at least one conductive material to form metal via structures and metal lines. The metal via structures are formed in the fourth via level, and are herein referred to as fourth-via-level metal via structures 724. The metal lines are formed in the fifth line level, and are herein referred to as fifth-line-level metal lines 785. The combination of all dielectric material layers that are formed above the substrate 8 is herein collectively referred to as dielectric material layers 60.

According to an aspect of the present disclosure, a bit line connection via structure 93 can be formed within each repetition unit region RUR such that the bit line connection via structure 93 contacts a middle portion of the spin current metal line 40 within the repetition unit region RUR. If the first upper-level dielectric material layer 608 is formed at the fourth via level and the fifth line level, the bit line connection via structures 93 may be comprise fourth-via-level metal via structure 724. Each bit line connection via structure 93 constitutes an electrode of both SOT MRAM cell MTJs (20A, 20B) located in the same repetition unit region RUR, and is herein referred to as a bit-line-connection electrode. Each bit line connection via structure 93 may be contacted by a respective bit-line-connection metal line which comprises a respective one of the fifth-line-level metal lines 785.

A subset of the fifth-line-level metal lines 785 that is formed on the top surfaces of the selector elements 80 comprises upper electrodes 92 of the MTJs of the SOT MRAM cells (20A, 20B). A pair of upper electrodes 92 is formed within each repetition unit region RUR. The pair of upper electrodes 92 comprises a first upper electrode 921 contacting a top surface of the first selector element 801, and a second upper electrode 922 contacting a top surface of the second selector element 802. In one embodiment, the exemplary structure may comprise an SOT magnetoresistive memory device including a two-dimensional array of repetition units RU. Each repetition unit RU can be formed within the volume of a respective one of the repetition unit regions RUR.

In one embodiment, the SOT magnetoresistive memory device may comprise word lines that are laterally spaced apart from each other along the first horizontal direction hd1 and laterally extend along a second horizontal direction hd2 that is perpendicular to the first horizontal direction hd1. In this case, the first upper electrode 921 and the second upper electrode 922 of each of the repetition units RU may comprise portions of the word lines. The first upper electrode 921 comprises an upper word line of the first SOT MRAM cell MTJ 20A, while the second upper electrode 922 comprises an upper word line of the second SOT MRAM cell MTJ 20B.

Generally, the formation of metal lines 48 is optional because their purpose is to connect circuits below spin-current-level dielectric material layer 606 with interconnects and wires above spin-current-level dielectric material layer 606. In this configuration, a subset of the four-via-level metal via structures 724 may be in direct contact with a subset of the third-via-level metal via structures 723.

A SOT magnetoresistive memory device includes a two-dimensional periodic array of repetition units RU. Each repetition unit RU may comprise a pair of SOT memory cells that includes a pair of lower electrodes 91, a pair of MTJ-containing pillar structures (i.e., a pair of SOT MRAM cell MTJs) 20 (e.g., 20A and 20B), a spin current metal line 40 located above the pair of MTJ-containing pillar structure 20, a pair of selector elements 80 (i.e., 801 and 802) located on a first end and a second end of the spin current metal line 40, respectively, a pair of upper electrodes 92 contacting a top surface of a respective one of the selector elements 80, and a bit-line-connection electrode comprising a bit line connection via structure 93 contacting a middle portion of the spin current metal line 40.

In one embodiment, the SOT magnetoresistive memory device comprises word lines 30 that are laterally spaced apart along a first horizontal direction hd1 and laterally extend along the second horizontal direction hd2. Thus, the upper electrodes 92 that are arranged in a row along the second horizontal direction hd2 together comprise a respective word line 30. In this case, each of the word lines 30 comprises a plurality of portions comprising respective row of the upper electrodes 92 of the SOT magnetoresistive memory device. Alternatively, the upper electrodes 92 may comprise discrete upper electrodes arranged in a row along the second horizontal direction hd2 which are electrically connected to separate respective word line 30.

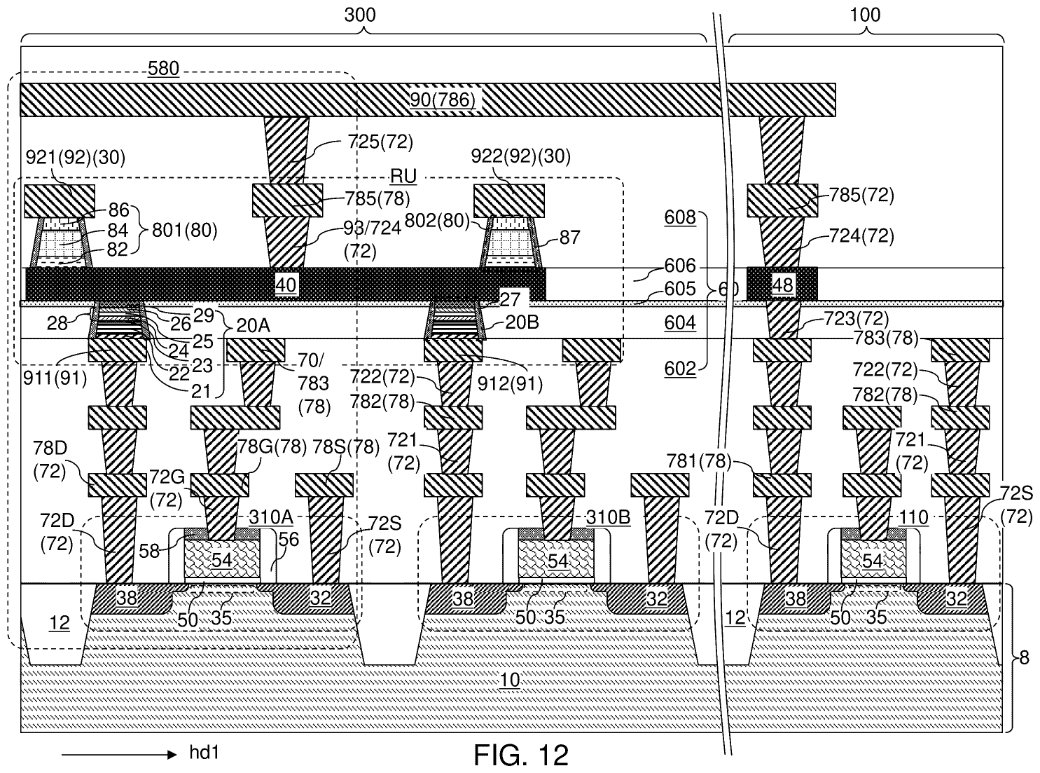

Referring to FIG. 12, additional upper-level dielectric material layers 608 can be formed above the first upper-level dielectric material layer 608. Additional upper-level metal interconnect structures (725, 786) may be formed in the additional upper-level dielectric material layers 608. The additional upper-level metal interconnect structures (725, 786) may comprise metal via structures 72 such as fifth-via-level metal via structures 725 contacting top surfaces of the fifth-line-level metal lines 785, and metal lines 78, such as sixth-line-level metal line structures 786. A subset of the sixth-line-level metal line structures 786 may comprise bit lines 90. Each bit line 90 may laterally extend along the first horizontal direction hd1 and may be laterally spaced apart along the second horizontal direction hd2. Each of the bit lines 90 can be electrically connected to a respective column of bit-line-connection electrodes (which comprise bit line connection via structures 93). Each bit line 90 may be electrically connected to a respective device in the peripheral circuit, such as a respective sense amplifier and bit line driver.

Generally, each bit line 90 may be formed over the first selector elements 801, the second selector elements 802, the word lines 30, and the bit line connection via structures 93 within a respective column of repetition units RU, and may be electrically connected to each of the bit line connection via structures 93 within the respective column of repetition units RU. The spin-orbit-torque (SOT) magnetoresistive memory device comprises an array of repetition units RU each containing a pair of SOT memory cells. The first SOT memory cell (20A, 40, 801) includes the first MTJ 20A, the first selector 801 and a first portion of the spin current metal line (i.e., a first portion of the common SOT metal layer 40). The second SOT memory cell (20B, 40, 802) includes the second MTJ 20B, the second selector 802 and a second portion of the spin current metal line 40. In one embodiment, the array of repetition units RU comprises a two-dimensional periodic array of repetition units RU arranged along the first horizontal direction hd1 and along the second horizontal direction hd2, and each of the bit lines 90 is electrically connected to middle portions of a respective column of spin current metal lines 40 that are arranged along the first horizontal direction hd1. Each unit cell 580 includes a respective SOT memory cell (20, 40, 80) and a respective transistor 310 (e.g., 310A or 310B) of the respective SOT memory cell. For example, the first transistor 310A is electrically connected to the first MTJ 20A of the first SOT memory cell (20A, 40, 801), and the second transistor 310B is electrically connected to the second MTJ 20B of the second SOT memory cell (20B, 40, 802).

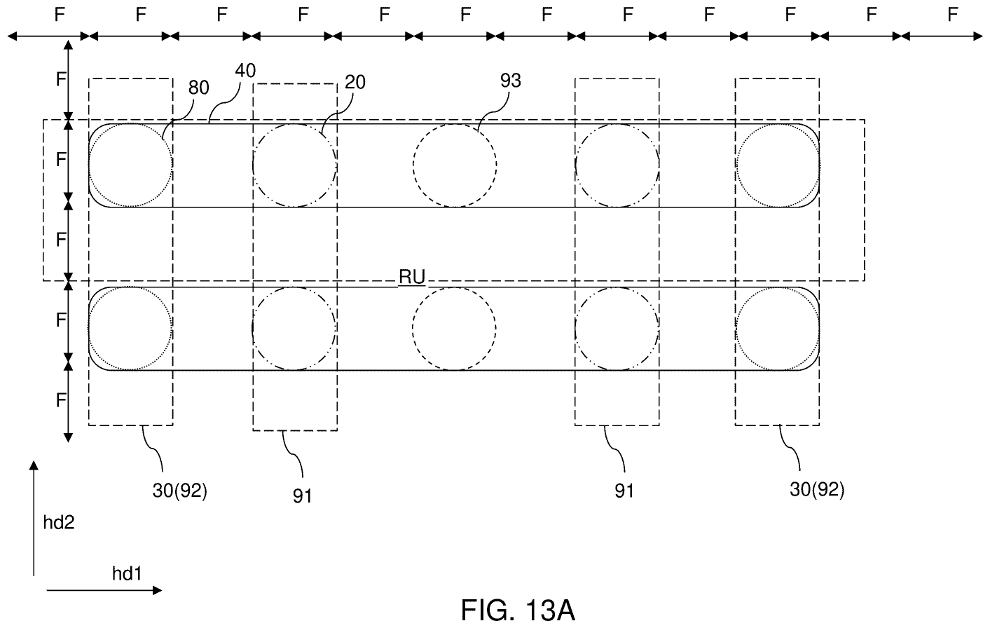

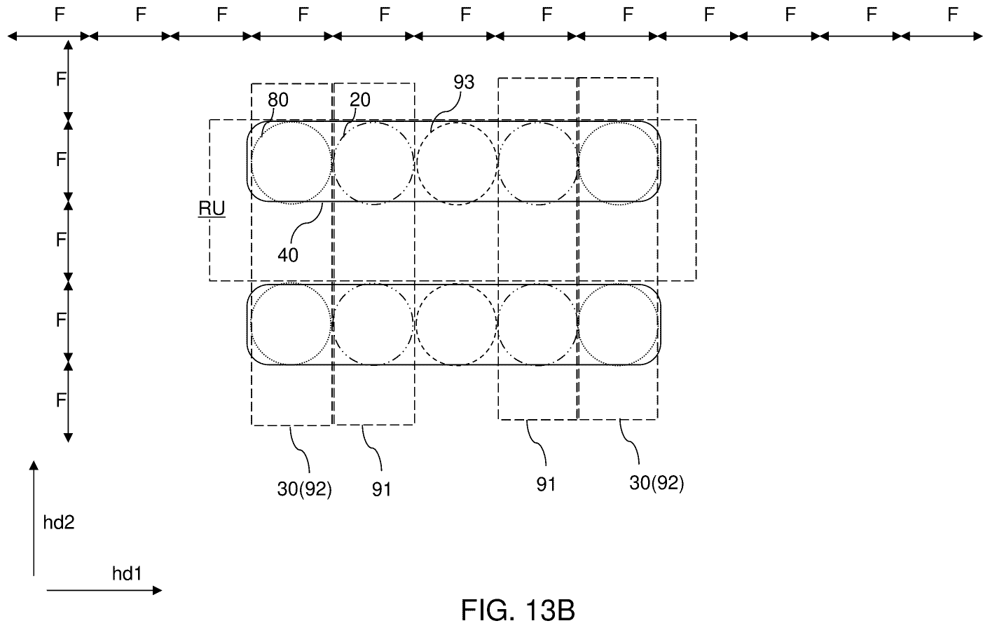

FIG. 13A is a plan view of a first configuration of the exemplary structure after the processing steps of FIG. 12. FIG. 13B is a plan view of a second configuration of the exemplary structure after the processing steps of FIG. 12. FIGS. 13A and 13B illustrate exemplary layouts for embodiment repetition units RU for the SOT memory array. Each repetition RU in FIGS. 13A and 13B comprises memory components of a pair of unit cells 580 in the memory device 500 of FIG. 1.

FIG. 13A illustrates a first layout in which a repetition unit RU occupies an area corresponding to 20 times the square of a minimum lithographic width F. Each repetition unit RU includes backend-of-the-line (BEOL) components for two unit cells 580. The first layout occupies an area of 20 F² per two unit cells 580 in a plan view. Thus, the area per unit cell 580 in the plan view is 10 F². In one embodiment, each access transistor 310 may be designed to fit within the area of 10 F². Specifically, the repetition unit RU in FIG. 13A has a lateral dimension of 10 F along the first horizontal direction hd1 (which is the lengthwise direction of a spin current metal line 40) and a lateral dimension of 2 F along the second horizontal direction hd2, which is perpendicular to the first horizontal direction hd1. Word lines 30 may continuously extend along the second horizontal direction hd2. Each word line 30 may include a respective row of upper electrodes 92 that are merged together along the second horizontal direction hd2. Within each repetition unit RU, a pair of upper electrodes 92 and a pair of lower electrodes 91 are provided. Each upper electrode 92 may be laterally offset from a proximal MTJ-containing pillar structure 20 by about 1 F in a plan view, and a bit-line-connection electrode (as embodied as a bit line connection via structure 93) may be laterally offset from each of the MTJ-containing pillar structures 20 by about 1 F in the plan view.

FIG. 13B illustrates a second layout in which a repetition unit RU occupies an area corresponding to 12 times the square of a minimum lithographic width F. Each repetition unit RU includes backend-of-the-line (BEOL) components for two unit cells 580. The second layout occupies an area of 12 F² per two unit cells 580 in a plan view. Thus, the area per unit cell 580 in the plan view is 6 F². In one embodiment, each access transistor 310 may be designed to fit within the area of 5 F². Specifically, the repetition unit RU in FIG. 13B has a lateral dimension of 5 F along the first horizontal direction hd1 (which is the lengthwise direction of a spin current metal line 40) and a lateral dimension of 2 F along the second horizontal direction hd2, which is perpendicular to the first horizontal direction hd1. Word lines 30 may continuously extend along the second horizontal direction hd2. Each word line 30 may comprise or be electrically connected to a respective row of upper electrodes 92 that are merged together along the second horizontal direction hd2. Within each repetition unit RU, a pair of upper electrodes 92 and a pair of lower electrodes 91 are provided. An upper electrode 92 may border a proximal MTJ-containing pillar structure 20 in a plan view, and a bit-line-connection electrode (comprising a bit line connection via structure 93) may border each of the MTJ-containing pillar structures 20 without overlapping with the MTJ-containing pillar structures 20.

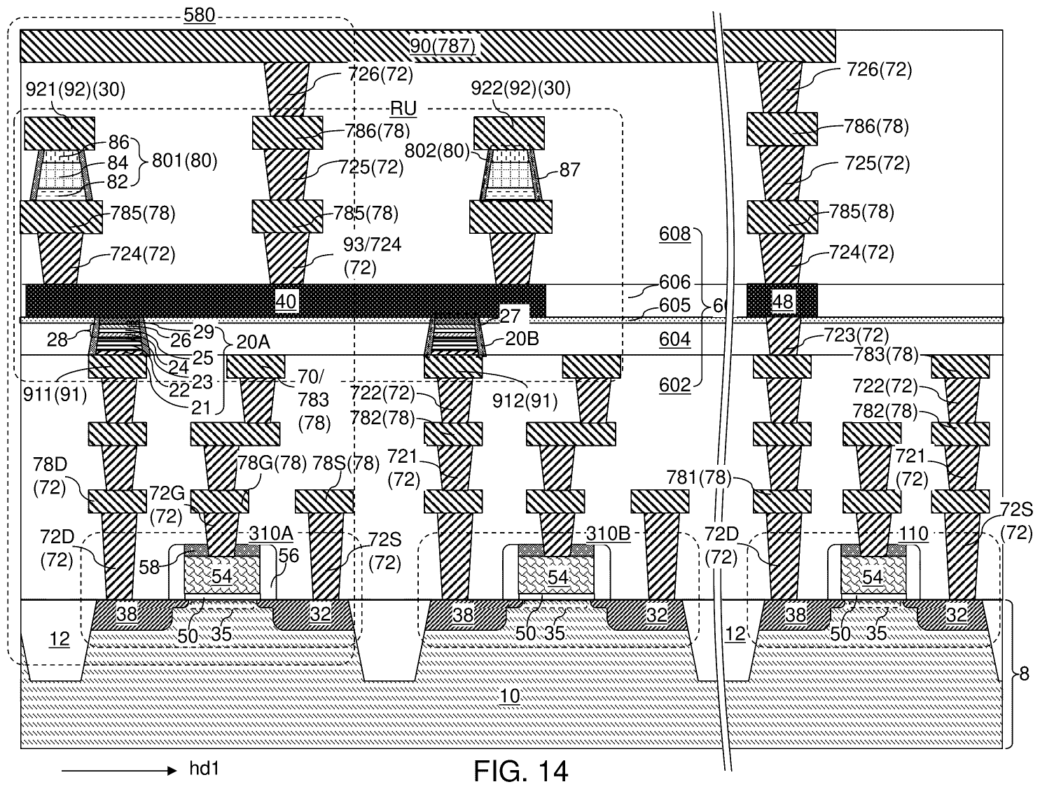

Referring to FIG. 14, a first alternative configuration of the exemplary structure may be derived from the exemplary structure by vertically shifting the two-dimensional array of selector elements 80 and the upper electrodes 92 to different vertical levels. For example, a vertical stack of a metal via structure 72 and a metal line 78, such as a vertical stack of a fourth-via-level metal via structure 724 and a fifth-line-level metal line 785, can be interposed between the spin current metal line 40 and each of the first selector element 801 and the second selector element 802. The fourth-via-level metal via structure 724 may be made of a hard magnetic material, such as cobalt, a samarium-cobalt alloy, an aluminum-nickel-cobalt (AlNiCo) alloy, or a neodymium-iron-boron alloy, for symmetry breaking. Fifth-via-level metal via structures 725 can be formed at the level of the selector elements 80. Sixth-line-level metal lines 786 can be formed over the fifth-via-level metal via structures 725. The upper electrodes 92 (e.g., word lines 30) may be formed as a subset of sixth-line-level metal lines 786. Additional metal interconnect structures can be formed over the sixth-line-level metal lines 786. For example, sixth-via-level metal via structures 726 and seventh-line-level metal lines 787 can be formed. Bit lines 90 may be formed as a subset of the seventh-line-level metal lines 787.

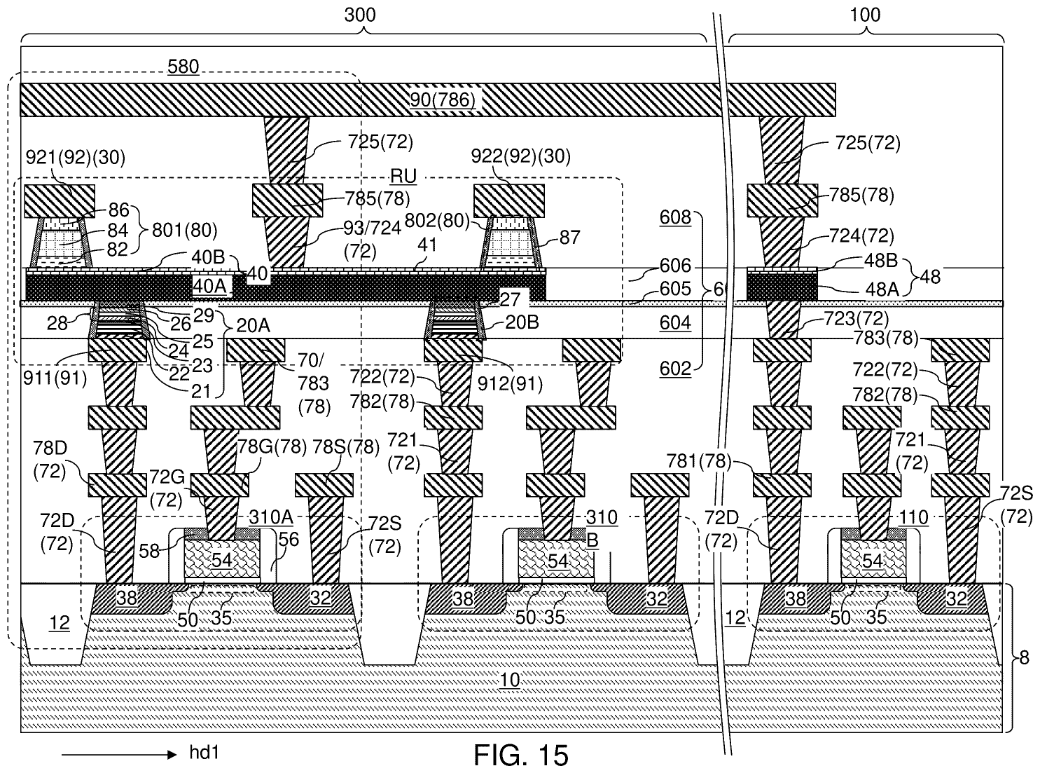

Referring to FIG. 15, a second alternative configuration of the exemplary structure may be derived from the exemplary structure or the first alternative configuration thereof by employing at least two materials for formation of spin current metal lines 40. For example, the spin current metal lines 40 can be formed by depositing a first metal having a first atomic number in a range from 72 to 79 at a first atomic percentage greater than 99 %, and a second metal having a second atomic number greater than the first atomic number for symmetry breaking. In this case, each spin current metal line 40 may comprise a vertical stack of a lower spin current metal line portion 40A including the first metal and an upper spin current metal line portion 40B including the second metal or metal alloy. In this case, each metal line 48 may comprise a lower metal line portion 48A including the first metal and an upper metal line portion 48B including the second metal.

Referring to all drawings and according to various embodiments of the present disclosure, a spin-orbit-torque (SOT) magnetoresistive memory device comprises an array of repetition units RU. Each of the repetition units RU comprises: a first magnetic tunnel junction (MTJ) 20A located over and electrically contacting a first lower electrode 911; a second MTJ 20B located over and electrically contacting a second lower electrode 912; a spin current metal line 40 located over a top surface of the first MTJ 20A and a top surface of the second MTJ 20B; a first selector element 801 electrically connected to a first end of the spin current metal line 40; and a second selector element 802 electrically connected to a second end of the spin current metal line 40.

In one embodiment, the memory device further comprises a bit line 90 electrically connected to the spin current metal line 40. In one embodiment, each of the repetition units RU comprises a bit line connection via structure 93 contacting a middle portion of the spin current metal line 40 and electrically connected to the bit line 90. In one embodiment, the top surface of the first MTJ 20A is located between the first selector element 801 and the bit line connection via structure 93 in a plan view, and the top surface of the second MTJ 20B is located between the second selector element 802 and the bit line connection via structure 93 in the plan view.

In one embodiment, the spin current metal line 40 laterally extends along a first horizontal direction hd1. In one embodiment, the first MTJ 20A and the second MTJ 20B are laterally spaced apart from each other along the first horizontal direction hd1; and the first selector element 801 and the second selector element 802 are laterally spaced apart from each other along the first horizontal direction hd1. In one embodiment, a lateral spacing between the first selector element 801 and the second selector element 802 is greater than a lateral spacing between the first MTJ 20A and the second MTJ 20B.

In one embodiment, each of the first selector element 801 and the second selector element 802 comprises a respective non-Ohmic material portion that provides non-Ohmic resistive characteristics as a function of an applied electrical voltage thereacross. In one embodiment, the non-Ohmic material portion comprises an ovonic threshold switch material. In one embodiment, each of the repetition units RU further comprises: a first word line 30 (921) located over and electrically contacting the first selector element 801; and a second word line 30 (922) located over and electrically contacting the second selector element 802. In one embodiment, the spin current metal line 40 laterally extends along a first horizontal direction hd1; the first and second word lines 30 are laterally spaced apart from each other along the first horizontal direction hd1 and laterally extend along a second horizontal direction hd2 which is perpendicular to the first horizontal direction hd1; the first word line physically contacts a top surface of the first selector element 801; and the second word line physically contacts a top surface of the second selector element 802.

In one embodiment, the array of repetition units RU comprises a two-dimensional periodic array of repetition units RU arranged along the first horizontal direction hd1 and along the second horizontal direction hd2. In one embodiment, the spin current metal line 40 comprises at least one metal having a respective an atomic number in a range from 72 to 79 at a total atomic percentage greater than 99 %.

In one embodiment, the first MTJ 20A comprises at least a portion of a first magnetic-tunnel-junction-containing (MTJ-containing) pillar structure 20; the second MTJ 20B comprises at least a portion of a second MTJ-containing pillar structure 20; and the spin current metal line 40 physically contacts a top surface of the first MTJ-containing pillar structure 20 and a top surface of the second MTJ-containing pillar structure 20.

In one embodiment, within each of the repetition units RU, the first MTJ-containing pillar structure 20 comprises a first free layer 26 underlying a first bottom surface segment of the spin current metal line 40; and the second MTJ-containing pillar structure 20 comprises a second free layer 26 underlying a second bottom surface segment of the spin current metal line 40. In one embodiment, within each of the repetition units RU, the first MTJ-containing pillar structure 20 further comprises a first tunneling barrier layer 25 and a first pinned layer 24 that underlie the first free layer 26; and the second MTJ-containing pillar structure 20 further comprises a second tunneling barrier layer 25 and a second pinned layer 24 that underlie the second free layer 26.

In one embodiment, the SOT magnetoresistive memory device further comprises a first access field effect transistor 310A underlying the array of repetition units, wherein the first lower electrode 911 is electrically connected to an electrical node of the first access field effect transistor 310A; and a second access field effect transistor 310B underlying the array of repetition units, wherein the second lower electrode 912 is electrically connected to an electrical node of the second access field effect transistor 310B.

In one embodiment, a data memory system comprises a chip. The chip contains the above described spin-orbit-torque (SOT) magnetoresistive memory device.

The structure of the memory device of various embodiments has a bottom-pinned configuration, where an MRAM transistor 310 array is located beneath rows of word lines 30. The word lines 30 are utilized to drive the selector elements 80, with an common spin current metal line 40 positioned between a pair of selector elements 80 within a repetition unit RU. Adjacent SOT memory cells (20, 40, 80) within this array share a bit line connection via structure 93 to a common bit line 90, thereby increasing device density.

To write data to the first MTJ 20A (i.e., to program the first SOT memory cell (20A, 40, 801) by flipping the magnetization direction of the first free layer 26), a voltage is applied between the first word line 30 (921) and the common bit line 90. The programming current flows from the first word line 30 (921) through the first selector element 801, the common spin current metal line 40, and the common bit line connection via structure 93 to the common bit line 90. The programming current flow through the common spin current metal line 40 adjacent to the first MTJ 20A flips the magnetization direction of the first free layer 26.

To write data to the second MTJ 20B (i.e., to program the second SOT memory cell (20B, 40, 802) by flipping the magnetization direction of the second free layer 26), a voltage is applied between the second word line 30 (922) and the common bit line 90. The programming current flows from the second word line 30 (922) through the second selector element 802, the common spin current metal line 40, and the common bit line connection via structure 93 to the common bit line 90. The programming current flow through the common spin current metal line 40 adjacent to the second MTJ 20B flips the magnetization direction of the second free layer 26.

To read data stored in the first MTJ 20A, a voltage is applied between the drain of the first transistor 310A and the common bit line 90. The read current flows from the first transistor 310A through the first MTJ 20A, the common spin current metal line 40, and the common bit line connection via structure 93 to the common bit line 90.

To read data stored in the second MTJ 20B, a voltage is applied between the drain of the second transistor 310B and the common bit line 90. The read current flows from the second transistor 310B through the second MTJ 20B, the common spin current metal line 40, and the common bit line connection via structure 93 to the common bit line 90.

During the writing process, an off-array capacitor may be utilized to discharge energy during the write cycle. Additionally, there may be leakage through the MRAM, which may provide supplementary spin-transfer torque (STT) MRAM writing via a half-bias MRAM transistor. For the reading process, the system reads through the MTJ and the top bit line 90 to detect the resistance state of the MTJ, which is influenced by the drive voltage and drive current. The system is capable of performing multi-bit reads across parallel smaller arrays to optimize performance.

According to an aspect of the present disclosure, a spin-orbit-torque (SOT) magnetoresistive memory device comprises a plurality of unit cells 580, which can be accessed through a row and column selected transistor array. In this configuration, each physical bit of an MRAM device is subjected to current through a spin current metal line 40, where the direction of the current flow alternates between neighboring bits on the same spin current metal line 40. This alternating current direction leads to data bits from every other physical memory cells being inverted to ensure correct data representation and retrieval. Alternatively, a bipolar write source may be employed to dynamically adjust the current direction along the spin current metal line 40, effectively compensating for the asymmetry in current flow and maintaining data integrity across the array.

The spin current metal line 40 breaks the symmetry for deterministic writing, employing techniques such as the use of a hard magnetic via metal to generate a magnetic field, as shown in FIG. 14. Alternatively, the spin current metal line 40 may also be constructed as a multi-layer structure, incorporating a soft ferromagnet or a synthetic antiferromagnet (SAF), or by stitching the spin current metal line 40A with an in-situ cap layer 40B, as shown in FIG. 15,.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of”replaces the word “comprise”or “include,”unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A spin-orbit-torque (SOT) magnetoresistive memory device comprising an array of repetition units, wherein each of the repetition units comprises:
a first magnetic tunnel junction (MTJ) located over and electrically contacting a first lower electrode;
a second MTJ located over and electrically contacting a second lower electrode;
a spin current metal line located over a top surface of the first MTJ and a top surface of the second MTJ;
a first selector element electrically connected to a first end of the spin current metal line; and
a second selector element electrically connected to a second end of the spin current metal line.

2. The SOT magnetoresistive memory device of claim 1, further comprising a bit line electrically connected to the spin current metal line.

3. The SOT magnetoresistive memory device of claim 2, wherein each of the repetition units further comprises a bit line connection via structure contacting a middle portion of the spin current metal line and electrically connected to the bit line.

4. The SOT magnetoresistive memory device of Clam 3, wherein:
the top surface of the first MTJ is located between the first selector element and the bit line connection via structure in a plan view; and
the top surface of the second MTJ is located between the second selector element and the bit line connection via structure in the plan view.

5. The SOT magnetoresistive memory device of claim 1, wherein the spin current metal line laterally extends along a first horizontal direction.

6. The SOT magnetoresistive memory device of claim 5, wherein:
the first MTJ and the second MTJ are laterally spaced apart from each other along the first horizontal direction; and
the first selector element and the second selector element are laterally spaced apart from each other along the first horizontal direction.

7. The SOT magnetoresistive memory device of claim 6, wherein a lateral spacing between the first selector element and the second selector element is greater than a lateral spacing between the first MTJ and the second MTJ.

8. The SOT magnetoresistive memory device of claim 1, wherein each of the first selector element and the second selector element comprises a respective non-Ohmic material portion.

9. The SOT magnetoresistive memory device of claim 8, wherein the non-Ohmic material portion comprises an ovonic threshold switch material.

10. The SOT magnetoresistive memory device of claim 2, wherein each of the repetition units further comprises:
a first word line located over and electrically contacting the first selector element; and
a second word line located over and electrically contacting the second selector element.

11. The SOT magnetoresistive memory device of claim 10, wherein:
the spin current metal line laterally extends along a first horizontal direction;
the first and the second word lines that are laterally spaced apart from each other along the first horizontal direction and laterally extend along a second horizontal direction which is perpendicular to the first horizontal direction;
the first word line physically contacts a top surface of the first selector element; and
the second word line physically contacts a top surface of the second selector element.

12. The SOT magnetoresistive memory device of claim 11, wherein the array of repetition units comprises a two-dimensional periodic array of repetition units arranged along the first horizontal direction and along the second horizontal direction.

13. The SOT magnetoresistive memory device of claim 1, wherein the spin current metal line comprises at least one metal having an atomic number in a range from 72 to 79 at a total atomic percentage greater than 50 %.

14. The SOT magnetoresistive memory device of claim 1, wherein:
the first MTJ comprises at least a portion of a first magnetic-tunnel-junction-containing (MTJ-containing) pillar structure;
the second MTJ comprises at least a portion of a second MTJ-containing pillar structure; and
the spin current metal line physically contacts a top surface of the first MTJ-containing pillar structure and a top surface of the second MTJ-containing pillar structure.

15. The SOT magnetoresistive memory device of claim 14, wherein, within each of the repetition units:
the first MTJ-containing pillar structure comprises a first free layer underlying a first bottom surface segment of the spin current metal line; and
the second MTJ-containing pillar structure comprises a second free layer underlying a second bottom surface segment of the spin current metal line.

16. The SOT magnetoresistive memory device of claim 15, wherein, within each of the repetition units:
the first MTJ-containing pillar structure further comprises a first tunneling barrier layer and a first pinned layer that underlie the first free layer; and
the second MTJ-containing pillar structure further comprises a second tunneling barrier layer and a second pinned layer that underlie the second free layer.

17. The SOT magnetoresistive memory device of claim 1, further comprising:
a first access field effect transistor underlying the array of repetition units, wherein the first lower electrode is electrically connected to an electrical node of the first access field effect transistor; and
a second access field effect transistor underlying the array of repetition units, wherein the second lower electrode is electrically connected to an electrical node of the second access field effect transistor.

18. A method of operating the magnetoresistive memory device of claim 10, comprising applying a voltage between the first word line and the bit line to flow a programming current from the first word line through the first selector element and the spin current metal line to bit line to flip a magnetization direction of a first free layer located in the first MTJ.

19. The method of claim 18, further comprising applying a voltage between the second word line and the bit line flow the programming current from the second word line through the second selector element and the spin current metal line to bit line to flip a magnetization direction of a second free layer located in the second MTJ.

20. The method of claim 19, further comprising:
reading data stored in the first MTJ by applying voltage between the first lower electrode and the bit line to flow a read current through the first MTJ and the spin current metal line; and
reading data stored in the second MTJ by applying voltage between the second lower electrode and the bit line to flow the read current through the second MTJ and the spin current metal line.

21. A data memory system comprising a chip, wherein said chip contains a spin-orbit-torque (SOT) magnetoresistive memory device comprising an array of repetition units, wherein each of the repetition units comprises:
a first magnetic tunnel junction (MTJ) located over and electrically contacting a first lower electrode;
a second MTJ located over and electrically contacting a second lower electrode;
a spin current metal line located over a top surface of the first MTJ and a top surface of the second MTJ;
a first selector element electrically connected to a first end of the spin current metal line; and
a second selector element electrically connected to a second end of the spin current metal line.

22. The data memory system of claim 21, wherein:
the first MTJ comprises at least a portion of a first magnetic-tunnel-junction-containing (MTJ-containing) pillar structure;
the second MTJ comprises at least a portion of a second MTJ-containing pillar structure; and
the spin current metal line physically contacts a top surface of the first MTJ-containing pillar structure and a top surface of the second MTJ-containing pillar structure.

23. The data memory system of claim 21, further comprising a bit line electrically connected to the spin current metal line.
